(19) United States
(12) Patent Application Publication
(10) Pub. No.: US 2025/0212642 A1
(43) Pub. Date: Jun. 26, 2025

(54) DISPLAY DEVICE AND METHOD FOR THE SAME

(71) Applicant: LG Display Co., Ltd., Seoul (KR)

(72) Inventors: Hyunsook JEON, Paju-si (KR); Moonsung KIL, Paju-si (KR); YongCheol KIM, Paju-si (KR)

(21) Appl. No.: 18/882,264

(22) Filed: Sep. 11, 2024

(30) Foreign Application Priority Data
Dec. 26, 2023 (KR) 10-2023-0190801

(51) Int. Cl. H10K 59/35; H10K 59/12; H10K 59/122

(52) U.S. Cl. CPC H10K 59/353; H10K 59/1201; H10K 59/122

(57) ABSTRACT

The present disclosure provides a display device and a method of manufacturing the display device. The display device includes a hole injection layer located on a bank layer. The hole injection layer including at least one hole. The display device has advantage of being driven with low power by preventing lateral leakage current.

### CROSS-REFERENCE TO RELATED APPLICATION

This application claims the priority benefit of Republic of Korea Patent Application No. 10-2023-0190801, filed on Dec. 26, 2023, in the Korean Intellectual Property Office, which is incorporated herein by reference for all purposes as if fully set forth herein.

### BACKGROUND

### Technical Field

The present disclosure relates to electronic devices with displays, and more specifically, to a display device and a method of manufacturing the display device.

### Description of the Related Art

As display technology has been developed to provide increased functions, display devices can provide an image capturing function, a sensing function, and the like, as well as an image display function.

To provide these functions, display devices may need to include an optical electronic device, such as a light receiving device, a camera, a sensor for detecting an image, and the like.

In order to receive light passing through the front surface of display devices, it may be desirable for such an optical electronic device to be located in an area of the display devices where incident light coming from the front surface can be increasingly received and detected.

To achieve the foregoing, in display devices, an optical electronic device has been designed to be located in a front portion of the display devices to allow a camera, a sensor, and/or the like as the optical electronic device to be increasingly exposed to incident light.

In order to install an optical electronic device in display devices in this manner, a bezel area of the display devices may be increased, or a notch or a hole may be needed to be formed in a display area of an associated display panel.

### BRIEF SUMMARY

The inventors of the present disclosure have recognized the benefits of display devices with higher transmittance, which allow the intended functions to be performed even when an optoelectronic device, such as a camera or sensor, that detects incident light and performs a predefined function, is attached to the display device.

Various embodiments of the present disclosure address the limitations of display devices found in the related art.

The inventors of the present disclosure have provided various embodiments of a display device capable of blocking the flow of lateral leakage current (LLC).

Further, the inventors have provided various embodiments of a display device capable of increasing the transmittance of a light-transmissive area by removing an electrode patterning material remaining in the light-transmissive area after patterning for an electrode layer is completed.

One or more aspects of the present disclosure may provide a display device capable of being driven with low power by preventing lateral leakage current and a method of manufacturing the display device.

One or more aspects of the present disclosure may provide a display device capable of improving the transmittance of a light-transmissive area and a method of manufacturing the display device.

According to one or more example embodiments of the present disclosure, a display device can be provided that includes: a substrate on which a normal area allowing a plurality of first pixels to be disposed and having a first resolution and an optical area allowing a plurality of second pixels to be disposed and having a second resolution lower than the first resolution are defined; a first electrode layer located over the substrate; a bank layer located over the substrate, covering a portion of the first electrode layer, and including an opening area; a hole injection layer located on the first electrode layer and the bank layer, and including at least one hole located on the bank layer; a hole transport layer located on the hole injection layer; and an emission layer located on the hole transport layer.

According to one or more example embodiments of the present disclosure, a method of manufacturing the display device can be provided that includes forming a first electrode layer, forming a hole injection layer on the first electrode layer, forming a hole in the hole injection layer, forming a hole transport layer on the hole injection layer and filling the hole with the hole transport layer, forming an electron transport layer on an emission layer, and forming a second electrode layer on the electron transport layer.

According to one or more example embodiments of the present disclosure, a display device can be provided that includes a substrate on which a normal area disposed with a plurality of first pixels and having a first resolution and an optical area disposed with a plurality of second pixels and having a second resolution lower than the first resolution are defined, wherein at least one of the normal area and the optical area comprises a plurality of subpixels, each of the plurality of subpixels comprises a light emitting element above the substrate, wherein the light emitting element comprises: a first electrode layer; a hole injection layer located on the first electrode layer and comprising at least one hole; a hole transport layer located on the hole injection layer; an emission layer located on the hole transport layer; and a second electrode layer located on the emission layer.

According to one or more aspects of the present disclosure, a display device may be provided that is capable of being driven with low power by preventing lateral leakage current, and a method of manufacturing the display device may be provided.

According to one or more aspects of the present disclosure, a display device may be provided that is capable of improving the transmittance of a light-transmissive area through process optimization and a method of manufacturing the display device.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIGS. 1A, 1B, 1C and 1D are plan views illustrating an example display device according to aspects of the present disclosure;

FIG. 2 illustrates an example system configuration of the display device according to aspects of the present disclosure;

FIG. 3 illustrates an example equivalent circuit of a subpixel in the display device according to aspects of the present disclosure;

FIG. 4 illustrates arrangements of subpixels in example three areas included in a display area of the display device according to aspects of the present disclosure;

FIG. 5A is an example enlarged plan view of a normal area NA in FIG. 4;

FIG. 5B is an example enlarged plan view of a first optical area OA1 in FIG. 4;

FIG. 5C is an example enlarged plan view of a second optical area OA2 in FIG. 4;

FIG. 6A is an example cross-sectional view taken along with line A-A′ of FIG. 5A;

FIG. 6B is an example cross-sectional view taken along line B-B′ of FIG. 5B;

FIGS. 6C and 6D are example cross-sectional views taken along line C-C′ of FIG. 5C;

FIGS. 7A, 7B, and 7C are example enlarged plan views of a first pixel group PG1, a second pixel group PG2, and a third pixel group PG3 of FIG. 5A;

FIGS. 8A, 8B, and 8C are flow diagrams illustrating an example method of manufacturing the display device according to aspects of the present disclosure;

FIG. 9 is an example schematic diagram illustrating the presence of lateral leakage current in the display device according to aspects of the present disclosure; and

FIG. 10 is an example graph illustrating changes in an extinction coefficient and a refractive index with respect to wavelengths in the display device according to aspects of the present disclosure.

### DETAILED DESCRIPTION

Reference will now be made in detail to example embodiments of the present disclosure, examples of which may be illustrated in the accompanying drawings. In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. In the following description, where the detailed description of the relevant known function or configuration may unnecessarily obscure aspects of the present disclosure, a detailed description of such known function or configuration may be omitted.

Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

The text “A and/or B” should be understood to mean “only A, only B, or both A and B.”

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, with reference to the accompanying drawings, various example embodiments of the present disclosure will be described in detail.

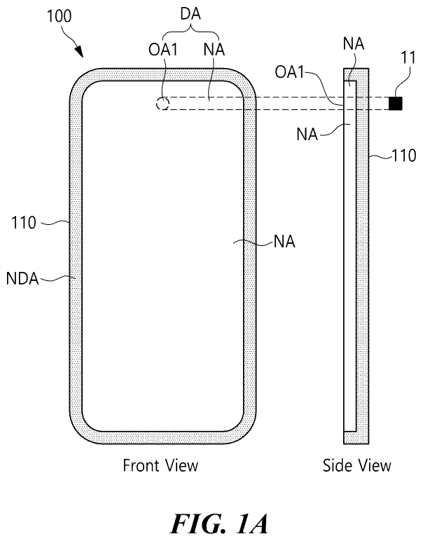

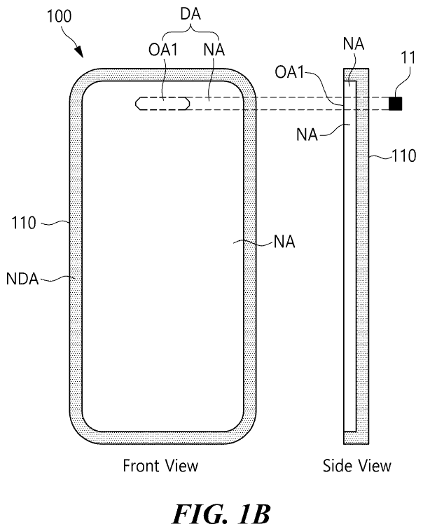

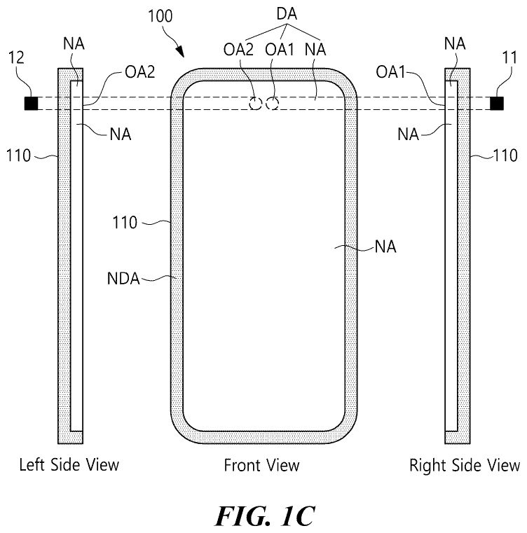

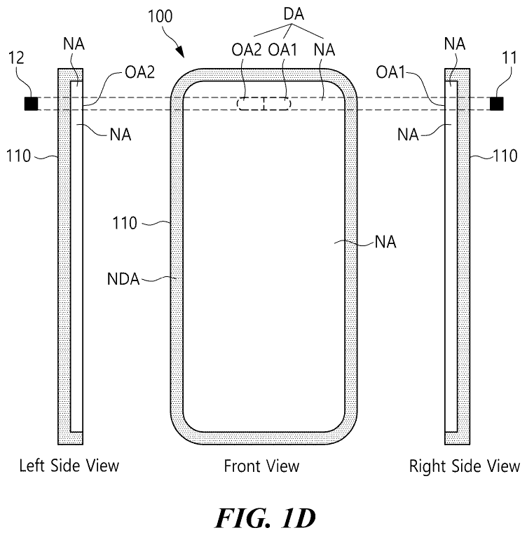

FIGS. 1A, 1B, 1C and 1D are plan views illustrating an example display device 100 according to aspects of the present disclosure.

Referring to FIGS. 1A, 1B, 1C, and 1D, in one or more example embodiments, the display device 100 may include a display panel 110 for displaying an image, and one or more optical electronic devices (11 and/or 12). Herein, an optical electronic device may be referred to as a light detector, a light receiver, or a light sensing device. An optical electronic device may include one or more of a camera, a camera lens, a sensor, a sensor for detecting images, or the like.

The display panel 110 may include a display area DA configured to allow one or more images to be displayed and a non-display area NDA in which an image is not displayed.

A plurality of subpixels may be disposed in the display area DA, and several types of signal lines for driving the plurality of subpixels may be disposed therein.

The non-display area NDA may refer to an area outside of the display area DA.

Several types of signal lines may be disposed in the non-display area NDA, and several types of driving circuits can be connected thereto.

At least a portion of the non-display area NDA may be bent to be invisible from the front surface of the display device 100 or may be covered by a case or housing (not shown) of the display device 100.

The non-display area NDA may be also referred to as a bezel or a bezel area.

Referring to FIGS. 1A, 1B, 1C and 1D, in one or more aspects, one or more optical electronic devices (11 and/or 12) included in the display device 100 may be located under, or in a lower portion of, the display panel 110 (an opposite side to the viewing surface thereof).

Light can enter the front surface (the viewing surface) of the display panel 110, pass through the display panel 110, reach one or more optical electronic devices (11 and/or 12) located under, or in the lower portion of, the display panel 110 (the opposite side of the viewing surface).

The one or more optical electronic devices (11 and/or 12) may be devices capable of receiving or detecting light passing through the display panel 110 and perform a predefined function based on the received light.

For example, the one or more optical electronic devices (11 and/or 12) may include one or more of the following: an image capture device such as a camera (an image sensor), and/or the like; or a sensor such as a proximity sensor, an illuminance sensor, and/or the like.

Referring to FIGS. 1A, 1B, 1C and 1D, in one or more aspects, the display area DA defined in the display panel 100 may include a normal area NA and one or more optical areas (OA1 and/or OA2). Herein, the term “normal area” NA may be an area that while being present in the display area DA, does not overlap with one or more optical electronic devices (11 and/or 12). The normal area NA may also be referred to as a non-optical area.

Referring to FIGS. 1A, 1B, 1C and 1D, the one or more optical areas (OA1 and/or OA2) may be one or more areas respectively overlapping the one or more optical electronic devices (11 and/or 12).

According to an example of FIG. 1A, the display area DA may include a first optical area OA1 and a normal area NA.

In this example, at least a portion of the first optical area OA1 may overlap with a first optical electronic device 11.

FIG. 1A illustrates a structure in which the first optical area OA1 has a circular shape, but the shape of the first optical area OA1 according to example embodiments of the present disclosure is not limited thereto.

For example, the first optical area OA1 may have an octagonal shape, or various polygonal shapes depending on design requirements.

According to an example of FIG. 1C, the display area DA may include a first optical area OA1, a second optical area OA2, and a normal area NA.

In the example of FIG. 1C, at least a portion of the normal area NA may be present between the first optical area OA1 and the second optical area OA2.

In this example, at least a portion of the first optical area OA1 may overlap with the first optical electronic device 11, and at least a portion of the second optical area OA2 may overlap with the second optical electronic device 12.

According to an example of FIG. 1D, the display area DA may include a first optical area OA1, a second optical area OA2, and a normal area NA.

In the example of FIG. 1D, the normal area NA may not be present between the first optical area OA1 and the second optical area OA2.

For example, the first optical area OA1 and the second optical area OA2 may contact each other (e.g., directly contact each other).

In this example, at least a portion of the first optical area OA1 may overlap with the first optical electronic device 11, and at least a portion of the second optical area OA2 may overlap with the second optical electronic device 12.

In one or more aspects, the one or more optical areas (OA1 and/or OA2) included in the display panel 110 or the display device 100 are needed to be configured with both an image display structure and a light transmissive structure.

For example, since the one or more optical areas (OA1 and/or OA2) are respective portions of the display area DA, therefore, it is desirable that subpixels for displaying images are disposed in the one or more optical areas (OA1 and/or OA2).

Further, to enable light entering the display panel 110 or the display device 100 to reach the one or more optical electronic devices (11 and/or 12), it is also desirable that each of the one or more optical areas (OA1 and/or OA2) is configured with a light transmissive structure.

It should be noted that even though the one or more optical electronic devices (11 and/or 12) are devices that need to receive light, the one or more optical electronic devices (11 and/or 12) may be located on the back of the display panel 110 (e.g., on an opposite side of the viewing surface thereof). Therefore, the one or more optical electronic devices (11 and/or 12) can receive light that has passed through the display panel 110.

For example, the one or more optical electronic devices (11 and/or 12) may not be exposed in the front surface (viewing surface) of the display panel 110 or the display device 100.

Accordingly, when a user views the front surface of the display device 110, the one or more optical electronic devices (11 and/or 12) are located so that they cannot be visible to the user.

The first optical electronic device 11 may be, for example, a camera, and the second optical electronic device 12 may be, for example, a sensor. The sensor may be a proximity sensor, an illuminance sensor, an infrared sensor, and/or the like.

In one or more aspects, the camera may be a camera lens, an image sensor, or a unit including at least one of the camera lens and the image sensor, and the sensor may be an infrared sensor capable of detecting infrared light.

In one or more aspects, the first optical electronic device 11 may be a sensor, and the second optical electronic device 12 may be a camera.

Hereinafter, for convenience of description, discussions are provided based on examples where the first optical electronic device 11 is a camera, and the second optical electronic device 12 is a sensor. It should be, however, understood that the scope of the present disclosure includes examples where the first optical electronic device 11 is the sensor, and the second optical electronic device 12 is the camera.

The camera may be, for example, a camera lens, an image sensor, or a unit including at least one of the camera lens and the image sensor.

In an example where the first optical electronic device 11 is a camera, this camera may be located on the back of (e.g., under, or in a lower portion of) the display panel 110, and be a front camera capable of capturing objects or images in a front direction of the display panel 110.

Accordingly, the user can capture an image or object through the camera that is invisible on the viewing surface while looking at the viewing surface of the display panel 110.

While the normal area NA and the one or more optical areas (OA1 and/or OA2) included in the display area DA have a common function of allowing images to be displayed, a difference is that the normal area NA may be an area where a light transmissive structure need not be implemented, but the one or more optical areas (OA1 and/or OA2) may be areas where a light transmissive structure need be implemented. Thus, in one or more aspects, the normal area NA may be an area where a light transmissive structure is not implemented or included, and the one or more optical areas (OA1 and/or OA2) may be areas in which a light transmissive structure is implemented or included.

In one or more aspects, the one or more optical areas (OA1 and/or OA2) may have a transmittance greater than or equal to a predetermined level, i.e., a relatively high transmittance, and the normal area NA may have a transmittance less than the predetermined level or not have light transmittance.

For example, the one or more optical areas (OA1 and/or OA2) may have a resolution, a subpixel arrangement structure, a number of subpixels per unit area, an electrode structure, a line structure, an electrode arrangement structure, a line arrangement structure, and/or the like different from that/those of the normal area NA.

For example, the number of subpixels per unit area in the one or more optical areas (OA1 and/or OA2) may be less than the number of subpixels per unit area in the normal area NA.

For example, the resolution of the one or more optical areas (OA1 and/or OA2) may be lower than that of the normal area NA.

Here, the number of subpixels per unit area may be a unit for measuring resolution, for example, referred to as pixels (or subpixels) per inch (PPI), which represents the number of pixels (or subpixels) within 1 inch.

For example, the number of subpixels per unit area in the first optical areas OA1 may be less than the number of subpixels per unit area in the normal area NA.

For example, the number of subpixels per unit area in the second optical areas OA2 may be greater than or equal to the number of subpixels per unit area in the first optical areas OA1.

In each of FIGS. 1A, 1B, 1C and 1D, the first optical area OA1 may have various shapes, such as a circle, an ellipse, a quadrangle, a hexagon, an octagon or the like.

In each of FIGS. 1C and 1D, the second optical area OA2 may have various shapes, such as a circle, an ellipse, a quadrangle, a hexagon, an octagon or the like.

The first optical area OA1 and the second optical area OA2 may have the same or substantially or nearly the same shape, or different shapes.

Referring to FIG. 1D, in the example where the first optical area OA1 and the second optical area OA2 contact each other (e.g., directly contact each other), the entire optical area including the first optical area OA1 and the second optical area OA2 may also have various shapes, such as a circle, an ellipse, a quadrangle, a hexagon, an octagon or the like.

Hereinafter, for convenience of description, discussions are provided based on examples where each of the first optical area OA1 and the second optical area OA2 has a circular shape. It should be, however, understood that the scope of the present disclosure includes examples where at least one of the first optical area OA1 and the second optical area OA2 has a shape other than the circular shape.

Herein, in examples where the display device 100 has a structure in which the first optical electronic device 11 such as a camera, and the like, is located under, or in a lower portion of, the display panel 100 without being exposed to the outside, such a display device 100 may be referred to as a display in which under-display camera (UDC) technology is applied.

According to these examples, the display device 100 can have an advantage of avoiding the size reduction of the display area DA because a notch or a camera hole for exposing a camera need not be formed in the display panel 110.

Indeed, since a notch or a camera hole for camera exposure need not be formed in the display panel 110, the display device 100 can provide further advantages of reducing the size of a bezel area, and improving the degree of freedom in design because such limitations to the design are removed.

Even when the one or more optical electronic devices (11 and/or 12) are located on the back of (e.g., under, or in a lower portion of) the display panel 110 of the display device 100 (e.g., hidden or not to be exposed to the outside), the one or more optical electronic devices (11 and/or 12) are needed to perform predefined functionalities by normally receiving or detecting light.

Further, in the display device 100, even when one or more optical electronic devices (11 and/or 12) are located on the back of (e.g., under, or in a lower portion of) the display panel 110 to be hidden and located to be overlap the display area DA, it is necessary for image display to be normally performed in the one or more optical areas (OA1 and/or OA2) overlapping the one or more optical electronic devices (11 and/or 12) in the display area DA. Thus, in one or more examples, even when one or more optical electronic devices (11 and/or 12) are located on the back of the display panel, images can be displayed in a normal manner (e.g., without reduction in image quality) in the one or more optical areas (OA1 and/or OA2) overlapping the one or more optical electronic devices (11 and/or 12) in the display area DA.

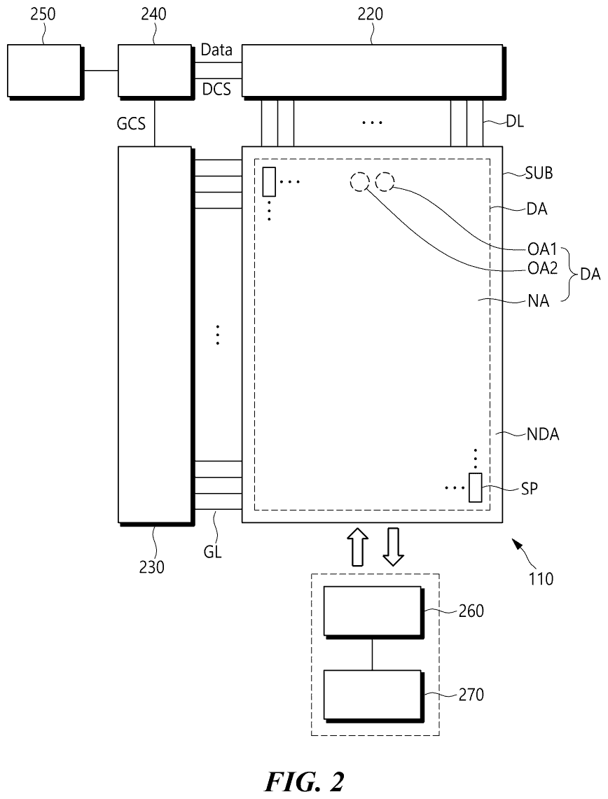

FIG. 2 illustrates an example system configuration of the display device 100 according to aspects of the present disclosure.

Referring to FIG. 2, the display device 100 may include the display panel 110 and a display driving circuit as components for displaying one or more images.

The display driving circuit may be a circuit for driving the display panel 110, and may include a data driving circuit 220, a gate driving circuit 230, a display controller 240, and other components.

The display panel 110 may include a display area DA configured to allow one or more images to be displayed and a non-display area NDA in which an image is not displayed.

The non-display area NDA may be an area outside of the display area DA, and may also be referred to as an edge area or a bezel area.

All or a portion of the non-display area NDA may be an area visible from the front surface of the display device 100, or an area that is bent and invisible from the front surface of the display device 100.

The display panel 110 may include a substrate SUB and a plurality of subpixels SP disposed on the substrate SUB.

The display panel 110 may further include various types of signal lines to drive the plurality of subpixels SP.

In one or more aspects, the display device 100 may be a liquid crystal display device, or the like, or a self-emission display device in which light is emitted from the display panel 210 itself.

In an example where the display device 100 is a self-emission display device, each of the plurality of subpixels SP may include a light emitting element.

For example, the display device 100 according to aspects of the present disclosure may be an organic light emitting display device in which light emitting elements are implemented using organic light emitting diodes (OLED).

In another example, the display device 100 according to aspects of the present disclosure may be an inorganic light emitting display device in which light emitting elements are implemented using inorganic material-based light emitting diodes.

In further another example, the display device 100 according to aspects of the present disclosure may be a quantum dot display device implemented with quantum dots, which are self-emission semiconductor crystals, as light emitting elements.

The structure of each of the plurality of subpixels SP may be differently configured or designed according to types of the display devices 100.

For example, in an example where the display device 100 is a self-emission display device including self-emission subpixels SP, each subpixel SP may include a self-emission light emitting element, one or more transistors, and one or more capacitors.

In one or more aspects, various types of signal lines arranged in the display device 100 may include, for example, a plurality of data lines DL for carrying data signals (which may be referred to as data voltages or image signals), a plurality of gate lines GL for carrying gate signals (which may be referred to as scan signals), and the like.

The plurality of data lines DL and the plurality of gate lines GL may intersect one another.

Each of the plurality of data lines DL may be con figured to extend in a first direction.

Each of the plurality of gate lines GL may be con figured to extend in a second direction.

For example, the first direction may be the column or vertical direction, and the second direction may be the row or horizontal direction.

In another example, the first direction may be the row or horizontal direction, and the second direction may be the column or vertical direction.

The data driving circuit 220 may be a circuit for driving the plurality of data lines DL, and can supply data signals to the plurality of data lines DL.

The gate driving circuit 230 may be a circuit for driving the plurality of gate lines GL, and can supply gate signals to the plurality of gate lines GL.

The display controller 240 may be a device for controlling the data driving circuit 220 and the gate driving circuit 230, and can control driving times for the plurality of data lines DL and driving times for the plurality of gate lines GL.

The display controller 240 can supply a data driving control signal DCS to the data driving circuit 220 to control the data driving circuit 220, and supply a gate driving control signal GCS to the gate driving circuit 230 to control the gate driving circuit 230.

The display controller 240 can receive input image data from a host system 250 and supply image data Data based on the input image data to the data driving circuit 220.

The data driving circuit 220 can supply data signals to the plurality of data lines DL according to driving timing control of the display controller 240.

The data driving circuit 220 can receive digital image data Data from the display controller 240, convert the received image data Data into analog data signals, and output the resulting analog data signals to the plurality of data lines DL.

The gate driving circuit 230 can supply gate signals to the plurality of gate lines GL according to timing control of the display controller 240.

The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit 220 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

In one or more aspects, the gate driving circuit 230 may be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique.

In one or more aspects, the gate driving circuit 230 may be disposed in the non-display area NDA of the display panel 110 by a gate-in-panel (GIP) technique.

The gate driving circuit 230 may be disposed on the substrate, or connected to the substrate.

In an example where the gate driving circuit 230 is implemented by the GIP technique, the gate driving circuit 230 may be disposed in the non-display area NDA of the substrate.

The gate driving circuit 230 may be connected to the substrate in an example where the gate driving circuit 230 is implemented by the chip-on-glass (COG) technique, the chip-on-film (COF) technique, or the like.

In one or more aspects, at least one of the data driving circuit 220 and the gate driving circuit 230 may be disposed in the display area DA of the display panel 110.

For example, at least one of the data driving circuit 220 and the gate driving circuit 230 may be configured not to overlap with subpixels SP, or configured to overlap with one or more, or all, of the subpixels SP, or at least respective one or more portions of one or more subpixels.

In one or more aspects, the data driving circuit 220 may be disposed in, and/or electrically connected to, but not limited to, one side or portion (e.g., an upper edge or a lower edge) of the display panel 110.

In one or more aspects, the data driving circuit 220 may be located in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

In one or more aspects, the gate driving circuit 230 may be located in, and/or electrically connected to, but not limited to, one side or portion (e.g., a left edge or a right edge) of the display panel 110.

In one or more aspects, the gate driving circuit 230 may be located in, and/or electrically connected to, but not limited to, two sides or portions (e.g., a left edge and a right edge) of the panel 110 or at least two of four sides or portions (e.g., an upper edge, a lower edge, the left edge, and the right edge) of the panel 110 according to driving schemes, panel design schemes, or the like.

The display controller 240 may be implemented in a separate component from the data driving circuit 220, or incorporated in the data driving circuit 220 and thus implemented in an integrated circuit.

The display controller 240 may be a timing controller used in the typical display technology or a controller or a control device capable of performing other control functions in addition to the function of the typical timing controller. In one or more embodiments, the display controller 240 may be a controller or a control device different from the timing controller, or a circuitry or a component included in the controller or the control device.

The display controller 240 may be implemented with various circuits or electronic components such as an integrated circuit (IC), a field programmable gate array (FPGA), an application specific integrated circuit (ASIC), a processor, and/or the like.

The display controller 240 may be mounted on a printed circuit board, a flexible printed circuit, and/or the like and be electrically connected to the gate driving circuit 220 and the data driving circuit 230 through the printed circuit board, flexible printed circuit, and/or the like.

The display controller 240 can transmit signals to, and receive signals from, the data driving circuit 220 via one or more predefined interfaces.

For example, such interfaces may include a low voltage differential signaling (LVDS) interface, an embedded clock point-point interface (EPI), a serial peripheral interface (SPI), and the like.

In one or more aspects, in order to further provide a touch sensing function, as well as an image display function, the display device 100 may include a touch sensor, and a touch sensing circuit capable of detecting whether a touch is applied by a touch object such as a finger, a pen, or the like, or detecting a location of the touch (or touch coordinates), by sensing the touch sensor.

The touch sensing circuit may include a touch driving circuit 260 capable of generating and providing touch sensing data by driving and sensing the touch sensor, a touch controller 270 capable of detecting whether a touch is applied or detecting a location of the touch (or touch coordinates) using the touch sensing data, and one or more other components.

The touch sensor may include a plurality of touch electrodes.

The touch sensor may further include a plurality of touch lines for electrically connecting the plurality of touch electrodes to the touch driving circuit 260.

The touch sensor may be implemented in the form of a touch panel outside of the display panel 110 or be integrated inside of the display panel 110.

In the example where the touch sensor is implemented in the form of the touch panel located outside of the display panel 110, such a touch sensor may be referred to as an add-on type.

In the example where the add-on type of touch sensor is disposed in the display device 100, the touch panel and the display panel 110 may be separately manufactured and combined in an assembly process.

The add-on type of touch panel may include a touch panel substrate and a plurality of touch electrodes disposed on the touch panel substrate.

In the example where the touch sensor is integrated inside of the display panel 110, the touch sensor may be formed on the substrate SUB together with signal lines and electrodes related to display driving during a process of manufacturing the display panel 110.

The touch driving circuit 260 can supply a touch driving signal to at least one of a plurality of touch electrodes, and sense at least one of the plurality of touch electrodes to generate touch sensing data.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on a capacitance between one or more touch electrode and an object such as a finger, a pen, and/or the like.

According to the self-capacitance sensing method, each of a plurality of touch electrodes can serve as both a driving touch electrode and a sensing touch electrode.

The touch driving circuit 260 can drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes.

According to the mutual-capacitance sensing technique, a plurality of touch electrodes may be divided into driving touch electrodes and sensing touch electrodes.

The touch driving circuit 260 can drive the driving touch electrodes and sense the sensing touch electrodes.

The touch driving circuit 260 and the touch controller 270 included in the touch sensing circuit may be implemented in separate devices or in a single device.

Further, the touch driving circuit 260 and the data driving circuit 220 may be implemented in separate devices or in a single device.

The display device 100 may further include a power supply circuit for supplying various types of power to the display driving circuit and/or the touch sensing circuit.

In some aspects, the display device 100 may be a mobile terminal such as a smart phone, a tablet, or the like, or a monitor, a television (TV), or the like. Such devices may be configured in various types, sizes, and shapes. The display device 100 according to aspects of the present disclosure are not limited thereto, and may include various types, sizes, and shapes configured to display information or images.

As described above, the display area DA of the display panel 110 may include the normal area NA and the one or more optical areas (OA1 and/or OA2) as illustrated in FIG. 1.

The normal area NA and the one or more optical areas (OA1 and/or OA2) may be areas configured to allow images to be displayed.

It should be noted here that the normal NA may be an area in which a light transmission structure need not be implemented, and the one or more optical areas (OA1 and/or OA2) may be areas in which a light transmission structure need be implemented.

As discussed above with respect to the examples of FIGS. 1A, 1B, 1C, and 1D, although the display area DA of the display panel 110 may include the one or more optical areas (OA1 and/or OA2) in addition to the normal area NA, for convenience of description, in the discussion that follows, it is assumed that the display area DA includes first and second optical areas (OA1 and OA2) and the normal area NA, as in FIGS. 1C and 1D; and the normal area NA thereof includes the normal areas NA in FIGS. 1A, 1B, 1C, and 1D, and the first and second optical areas (OA1 and/or OA2) thereof include the first optical areas OA1 in FIGS. 1A, 1B, 1C, and 1D and the second optical areas OA2 of FIGS. 1C and 1D, respectively, unless explicitly stated otherwise.

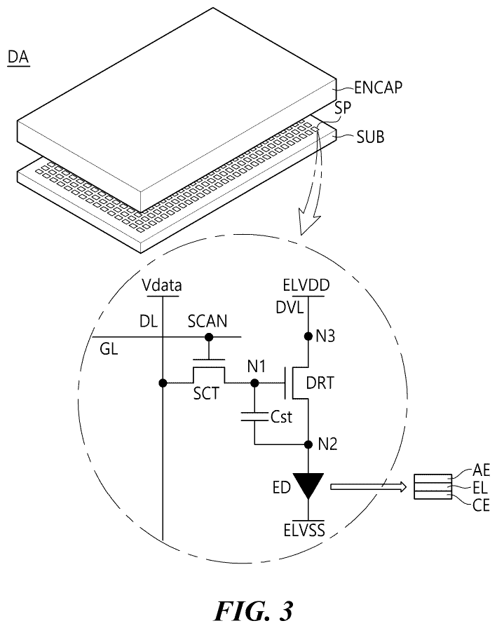

FIG. 3 illustrates an example equivalent circuit of a subpixel SP in the display panel 110 according to aspects of the present disclosure.

Each of subpixels SP disposed in the normal area NA, the first optical area OA1, and the second optical area OA2 included in the display area DA of the display panel 110 may include a light emitting element ED, a driving transistor DRT for driving the light emitting element ED, a scan transistor SCT for passing a data voltage Vdata to a first node N1 of the driving transistor DRT, a storage capacitor Cst for maintaining a voltage at an approximate constant level during one frame, and the like.

The driving transistor DRT may include the first node N1 to which a data voltage is applied, a second node N2 electrically connected to the light emitting element ED, and a third node N3 to which a driving voltage ELVDD delivered through a driving voltage line DVL is applied.

In the driving transistor DRT, the first node N1 may be a gate node, the second node N2 may be a source node or a drain node, and the third node N3 may be the drain node or the source node.

The light emitting element ED may include a first electrode layer AE, an emission layer EL, and a second electrode layer CE.

The first electrode layer AE may be a pixel electrode disposed in each subpixel SP, and may be electrically connected to the second node N2 of the driving transistor DRT of each subpixel SP.

The second electrode layer CE may be a common electrode commonly disposed in all or some of a plurality of subpixels SP. For example, a base voltage ELVSS may be applied to the second electrode layer CE.

For example, the first electrode layer AE may be a pixel electrode, and the second electrode layer CE may be a common electrode.

In another example, the first electrode layer AE may be the common electrode, and the second electrode layer CE may be the pixel electrode.

Hereinafter, for convenience of explanation, discussions are provided based on examples where the first electrode layer AE is a pixel electrode and the second electrode layer CE is a common electrode.

In one or more aspects, the light emitting element ED may be an organic light emitting diode (OLED), a micro light emitting diode (micro LED), a mini light emitting diode (mini LED), a quantum dot light emitting diode (QLED), an inorganic light emitting diode, or the like.

In an example where the light emitting element ED is an organic light emitting diode (OLED), an emission layer EL of the light emitting element ED may include an organic emission layer containing an organic material.

The scan transistor SCT can be turned on and off by a scan signal SCAN, which is a gate signal applied through a gate line GL, and be electrically connected between the first node N1 of the driving transistor DRT and a data line DL.

The storage capacitor Cst may be electrically connected between the first node N1 and the second node N2 of the driving transistor DRT.

Each subpixel SP may include two transistors (2T: DRT and SCT) and one capacitor (1C: Cst) (which may be referred to as a “2T1C structure”) as illustrated in FIG. 3, and in some cases, may further include one or more transistors, or further include one or more capacitors.

The storage capacitor Cst may be an external capacitor intentionally designed to be located outside of the driving transistor DRT, other than an internal capacitor, such as a parasitic capacitor (e.g., a Cgs or a Cgd), that may be formed between the first node N1 and the second node N2 of the driving transistor DRT.

In one or more aspects, each of the driving transistor DRT and the scan transistor SCT may be an n-type transistor, or a p-type transistor.

In one or more aspects, each of the driving transistor DRT and the scan transistor SCT may be a low-temperature polycrystalline silicon transistor.

However, example embodiments of the present disclosure are not limited thereto. For example, at least one of the driving transistor DRT and the scan transistor SCT may be an oxide thin film transistor.

Since circuit elements (in particular, a light emitting element ED implemented with an organic light emitting diode including an organic material) included in each subpixel SP are vulnerable to external moisture or oxygen, an encapsulation layer ENCAP may be configured to cover the circuit elements (e.g., the light emitting element ED) in order to prevent external moisture or oxygen from penetrating into such circuit elements.

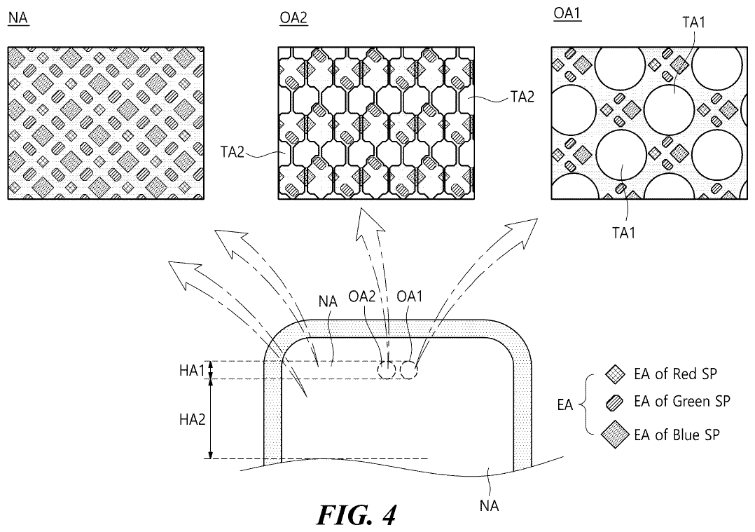

FIG. 4 illustrates arrangements of subpixels SP in example three areas (NA, OA1, and OA2) included in the display area of the display device 100 according to aspects of the present disclosure.

Referring to FIG. 4, in one or more example embodiments, a plurality of subpixels SP may be disposed in each of the normal area NA, the first optical area OA1, and the second optical area OA2 included in the display area DA.

The plurality of subpixels SP may include, for example, a red subpixel (Red SP) emitting red light, a green subpixel (Green SP) emitting green light, and a blue subpixel (Blue SP) emitting blue light.

Accordingly, each of the normal area NA, the first optical area OA1, and the second optical area OA2 may include one or more light emitting areas EA of one or more red subpixels (Red SP), and one or more light emitting areas EA of one or more green subpixels (Green SP), and one or more light emitting areas EA of one or more blue subpixels (Blue SP).

Referring to FIG. 4, the normal area NA may not include a light transmissive structure, but may include light emitting areas EA.

In one or more aspects, each of the first optical area OA1 and the second optical area OA2 may be needed to include a light transmissive structure, as well as light emitting areas EA.

Accordingly, in one or more aspects, the first optical area OA1 may include one or more light emitting areas EA and one or more first transmissive areas TA1, and the second optical area OA2 may include one or more light emitting areas EA and one or more second transmissive areas TA2.

Light emitting areas EA and transmissive areas (TA1 and TA2) may be distinct from each other by whether light is allowed to be transmitted or not.

For example, the light emitting areas EA may be areas configured not to allow light to transmit (e.g., not to allow light to transmit to the back of the display panel), and the transmission areas (TA1 and TA2) may be areas configured to allow light to transmit (e.g., to allow light to transmit to the back of the display panel).

Light emitting areas EA and transmissive areas (TA1 and TA2) may be also distinct from each other by whether a second electrode layer CE (e.g., the second electrode layer CE of FIG. 3) is disposed or not.

For example, while the second electrode layer CE may be disposed in the light emitting areas EA, the second electrode layer CE may not be disposed in the transmissive areas (TA1 and TA2).

In one or more aspects, a protective layer (not shown) may be disposed in the transmissive areas (TA1 and TA2).

The protective layer may include an organic material and be configured to cover at least a portion of the transmissive areas (TA1 and TA2) using a fine metal mask (FMM).

The protective layer may be used to improve the light transmittance of the transmissive areas (TA1 and TA2) and to effectively pattern the second electrode layer CE formed in a corresponding light emitting area EA.

For example, after forming the protective layer in the transmissive areas (TA1 and TA2) using the fine metal mask (FMM), the second electrode layer CE may be deposited in a corresponding light emitting area EA using an open metal mask (OMM), and thus, the second electrode layer CE can be effectively formed in the light emitting area EA except for the protective layer. For example, by appropriately controlling the surface energy of the protective layer, the second electrode layer CE may not be formed on the protective layer and be formed only in an area where the protective layer is not present.

Accordingly, the protective layer and the second electrode layer CE may be located in the same layer.

However, example embodiments of the present disclosure are not limited to the example where the protective layer is formed and remained in the transmissive areas (TA1 and TA2). For example, to increase the transmittance of the transmissive areas (TA1 and TA2), the protective layer may be removed after the second electrode layer CE is formed.

For example, the protective layer may not remain in the transmissive areas (TA1 and TA2).

In one or more aspects, light shield layers may be disposed in light emitting areas EA, and a light shield layer may not be disposed in transmissive areas (TA1 and TA2).

Since the first optical area OA1 includes first transmissive areas TA1 and the second optical area OA2 includes second transmissive areas TA2, both the first optical area OA1 and the second optical area OA2 may be areas configured to allow light to be transmitted.

A transmittance (a degree of transmission) of the first optical area OA1 and a transmittance (a degree of transmission) of the second optical area OA2 may be substantially the same.

Herein, substantially the same may mean a degree of being considered as being equivalent to each other taking into account minute differences due to errors in the process of manufacturing the display panel 110 or display device 100.

According to this definition, first transmissive areas TA1 of the first optical area OA1 and second transmissive areas TA2 of the second optical area OA2 may have substantially the same shape or size.

In one or more aspects, even when first transmissive areas TA1 of the first optical area OA1 and second transmissive areas TA2 of the second optical area OA2 have different shapes or sizes, a ratio of the first transmissive areas TA1 in the first optical area OA1 and a ratio of the second transmissive areas TA2 in the second optical area OA2 may be substantially the same.

However, example embodiments of the present disclosure are not limited thereto. For example, a transmittance (a degree of transmission) of the first optical area OA1 and a transmittance (a degree of transmission) of the second optical area OA2 may be different from each other.

In this implementation, first transmissive areas TA1 of the first optical area OA1 and second transmissive areas TA2 of the second optical area OA2 may have different shapes or sizes.

In one or more aspects, even when first transmissive areas TA1 of the first optical area OA1 and second transmissive areas TA2 of the second optical area OA2 have substantially the same shape or size, a ratio of the first transmissive areas TA1 in the first optical area OA1 and a ratio of the second transmissive areas TA2 in the second optical area OA2 may be different from each other.

For example, in an example where the first optical electronic device 11 overlapping with the first optical area OA1 is a camera, and the second optical electronic device 12 overlapping with the second optical area OA2 is a sensor for detecting images, the camera may need a greater amount of light than the sensor.

In this example, a transmittance (a degree of transmission) of the first optical area OA1 may be greater than a transmittance (a degree of transmission) of the second optical area OA2.

In this implementation, all or each of first transmissive areas TA1 of the first optical area OA1 may have an area greater than all or each of second transmissive areas TA2 of the second optical area OA2.

In one or more aspects, even when first transmissive areas TA1 of the first optical area OA1 and second transmissive areas TA2 of the second optical area OA2 have substantially the same size, a ratio of the first transmissive areas TA1 in the first optical area OA1 may be greater than a ratio of the second transmissive areas TA2 in the second optical area OA2.

In one or more aspects, as shown in FIG. 4, first transmissive areas TA1 of the first optical area OA1 may have circular shapes in a cross-sectional view, but example embodiments of the present disclosure for shapes of the first transmissive areas TA1 are not limited thereto.

For example, the first transmissive areas TA1 of the first optical area OA1 may have octagonal shapes in a plan view, or may have elliptical or polygonal shapes.

As discussed above, by changing the shape of the first transmissive areas TA1, the transmittance of the first transmissive areas TA1 can be adjusted, and the area or size of light emitting areas of the first optical area OA1 can be adjusted.

Hereinafter, for convenience of explanation, discussions are provided based on examples where the transmittance (the degree of transmission) of the first optical area OA1 is greater than that of the second optical area OA2.

Further, as shown in FIG. 4, transmissive areas (TA1 and TA2) may be referred to as transparent areas, and transmittance may also be referred to as transparency.

In discussions that follow, as shown in FIG. 4, it is assumed that the first optical area OA1 and the second optical area OA2 are located at an upper portion of the display area DA of the display panel 110, and are disposed side by side left and right.

Referring to FIG. 4, a horizontal display area where the first optical area OA1 and the second optical area OA2 are disposed may be referred to as a first horizontal display area HA1, and a horizontal display area where the first optical area OA1 and the second optical area OA2 are not disposed may be referred to as a second horizontal display area HA2.

Referring to FIG. 4, the first horizontal display area HA1 may include a portion of the normal area NA, the first optical area OA1, and the second optical area OA2.

The second horizontal display area HA2 may include only the normal area NA.

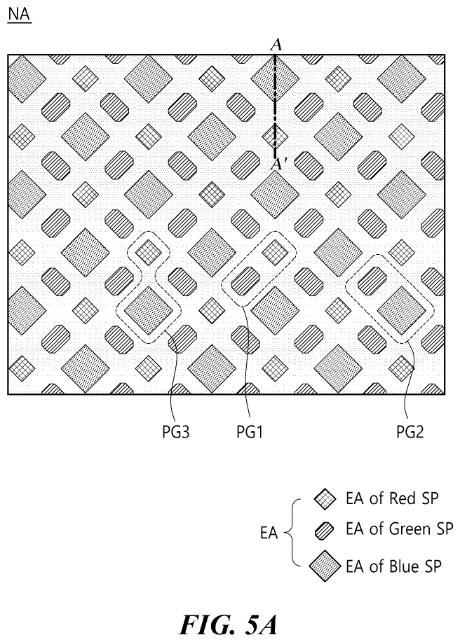

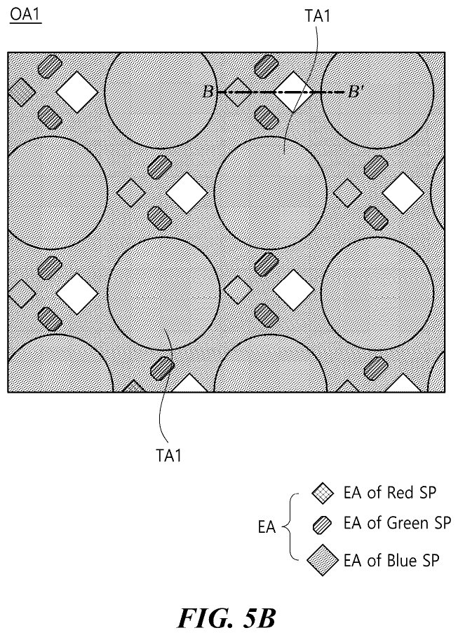

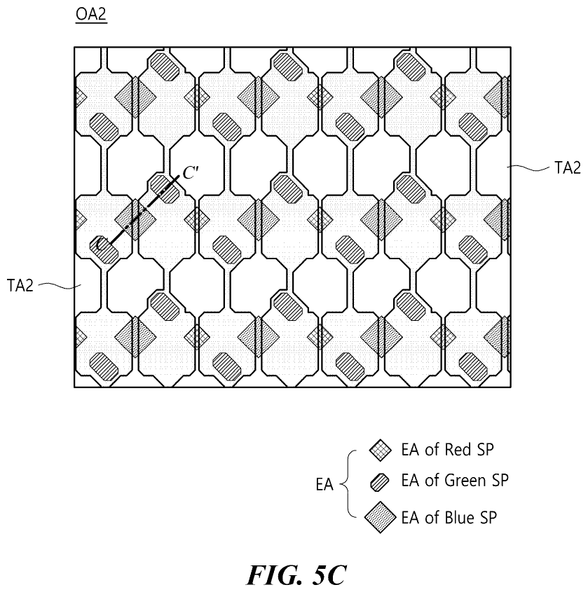

FIGS. 5A to 5C are example enlarged plan views of the three areas (NA, OA1, and OA2) in FIG. 4.

Referring to FIG. 5A, the normal area NA may include a plurality of subpixels SP arranged in a matrix form.

Each of the subpixels SP may be one subpixel SP among a red subpixel (Red SP), a green subpixel (Green SP), and a blue subpixel (Blue SP). One unit pixel may be implemented by including two or more of the red subpixel (Red SP), the green subpixel (Green SP), and the blue subpixel (Blue SP).

In one or more aspects, each of the plurality of subpixels SP may further include a white subpixel.

In one or more aspects, two subpixels may be implemented as one pixel using a subpixel rendering algorithm.

For example, each of first pixel groups PG1 may be configured to include a red subpixel Red SP and a green subpixel Green SP.

In another example, each of second pixel groups PG2 may be configured to include a blue subpixel Blue SP and a green subpixel Green SP.

In another example, each of third pixel groups PG3 may be configured to include a blue subpixel Blue SP and a red subpixel Red SP.

In these examples, such insufficient color representation in each of the pixel groups (PG1, PG2, and PG3) may be compensated for based on an average value of corresponding color data of neighboring pixels through a subpixel rendering algorithm.

FIG. 5A illustrates that subpixels are disposed such that a plurality of pixels each including a red subpixel Red SP, a green subpixel Green SP, a blue subpixel Blue SP, and a green subpixel Green SP are disposed in a zigzag form in the x-axis direction, but example embodiments of the present disclosure are not limited thereto.

FIGS. 5B and 5C are enlarged plan views of the optical areas (OA1 and OA2).

The configuration of subpixels SP shown in FIGS. 5B and 5C may be substantially the same as the configuration of the subpixels SP in FIG. 5A.

In addition, the configuration of the transmissive areas (TA1 and TA2) of FIGS. 5B and 5C may be substantially the same as the configuration of the transmissive areas (TA1 and TA2) in FIG. 4. Considering such similarities, discussions on the subpixels SP and the transmissive areas (TA1 and TA2) in FIGS. 5B and 5C are omitted for convenience of description.

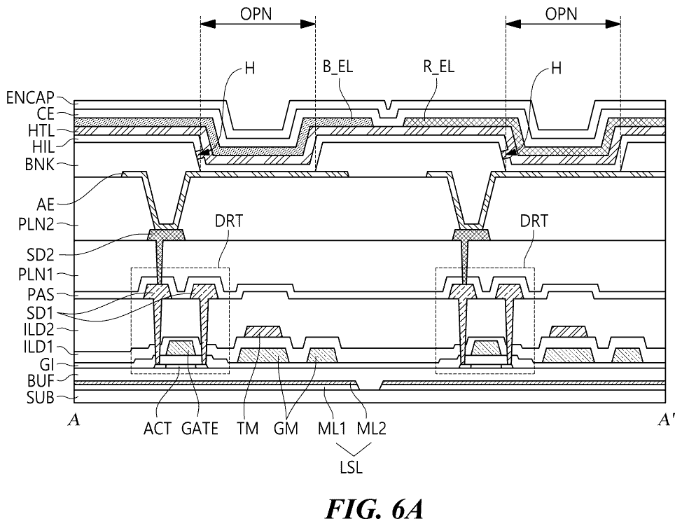

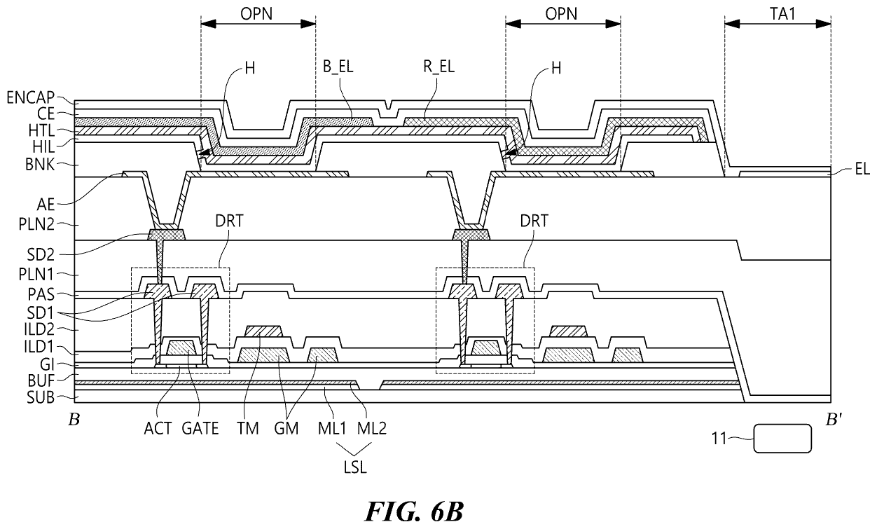

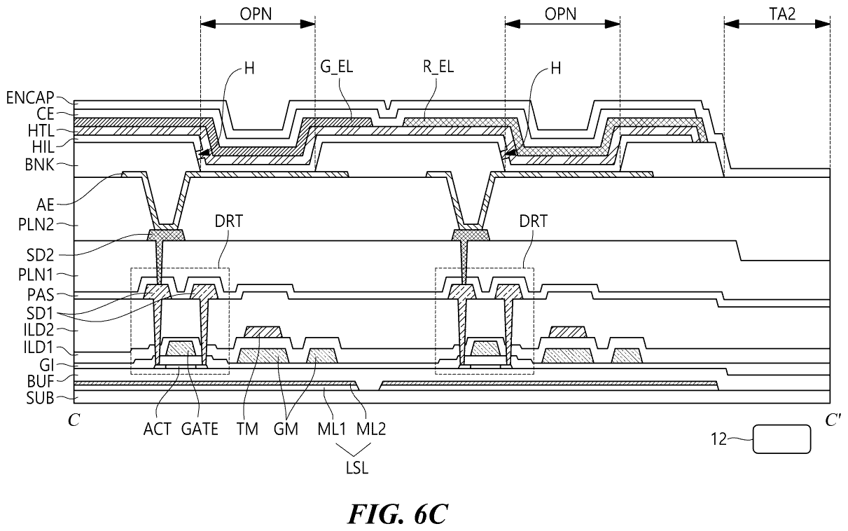

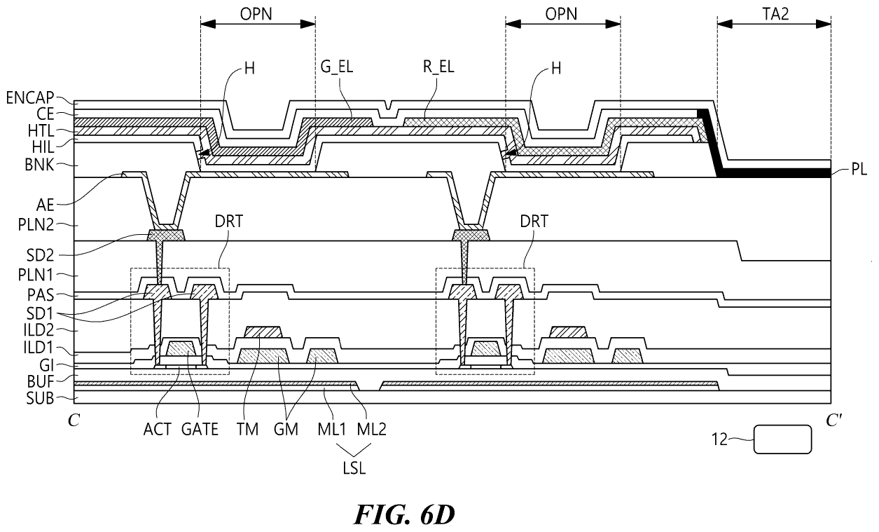

FIG. 6A is an example cross-sectional view taken along with line A-A′ of FIG. 5A.

Referring to FIG. 6A, various types of patterns (ACT, SD1, GATE, and the like) for forming one or more transistors such as a driving transistor DRT, a scan transistor SCT, and the like, various types of insulating layers (BUF, GI, ILD1, ILD2, PAS, and the like), and various types of metal patterns (TM, GM, ML1, ML2, and the like) may be disposed on or over the substrate SUB.

Referring to FIG. 6A, a buffer layer BUF may be disposed on a substrate SUB.

A first metal layer ML1 and a second metal layer ML2 may be disposed on the substrate SUB.

For example, the first metal layer ML1 and the second metal layer ML2 may be light shield layers LSL configured to shield light.

The buffer layer BUF may be disposed on the first metal layer ML1 and the second metal layer ML2.

An active layer ACT of a driving transistor DRT may be disposed on the buffer layer BUF.

A gate insulating layer GI may be configured to cover the active layer ACT.

The gate electrode GATE of the driving transistor DRT may be disposed on the gate insulating layer GI.

In one or more aspects, a gate material layer GM may be disposed on the gate insulating layer GI along with the gate electrode layer GATE of the driving transistor DRT at a location different from an area where the driving transistor DRT is formed.

A first interlayer insulating layer ILD1 may be configured to cover the gate electrode layer GATE and the gate material layer GM.

A metal pattern TM may be disposed on the first interlayer insulating layer ILD1.

The metal pattern TM may be located at a location different from the area where the driving transistor DRT is formed.

A second interlayer insulating layer ILD2 may be configured to cover the metal pattern TM on the first interlayer insulating layer ILD1.

Two first source-drain electrode pattern layers SD1 may be disposed on the second interlayer insulating layer ILD2.

One of the two first source-drain electrode pattern layers SD1 may be the source node of the driving transistor DRT, and the other thereof may be the drain node of the driving transistor DRT.

The two first source-drain electrode pattern layers SD1 may be electrically connected to respective portions (e.g., a first side and a second opposing side) of the active layer ACT through contact holes in the second interlayer insulating layer ILD2, the first interlayer insulating layer ILD1 and the gate insulating layer GI.

A portion of the active layer ACT, which overlaps with the gate electrode layer GATE, may act as a channel region.

For example, one of the two first source-drain electrode pattern layers SD1 may be connected to one side of the channel region of the active layer ACT, and the other one of the two first source-drain electrode pattern layers SD1 may be connected to the other side of the channel region of the active layer ACT.

A passivation layer PAS may be configured to cover the two first source-drain electrode pattern layers SD1.

At least one planarization layer PLN may be disposed on the passivation layer PAS.

The at least one planarization layer PLN may include a first planarization layer PLN1 and a second planarization layer PLN2.

The first planarization layer PLN1 may be disposed on the passivation layer PAS.

A second source-drain electrode pattern layer SD2 may be disposed on the first planarization layer PLN1.

The second source-drain electrode pattern layer SD2 may be connected to one of the two first source-drain electrode pattern layers SD1 (which may correspond to the second node N2 of the driving transistor DRT in the subpixel SP of FIG. 3) through a contact hole in the first planarization layer PLN1.

The second planarization layer PLN2 may be configured to cover the second source-drain electrode pattern layer SD2.

A light emitting element ED may be disposed on the second planarization layer PLN2.

The light emitting element ED may have a stack structure configured with a stack of layers as discussed below. A first electrode layer AE may be disposed on the second planarization layer PLN2.

The first electrode layer AE may include a material with a relatively high work function.

The first electrode layer AE may include, for example, a transparent conductive oxide, such as indium tin oxide (ITO), indium zinc oxide (IZO), zinc oxide (ZnO), aluminum zinc oxide (AZO), indium oxide (In2O3), tin oxide (SnO2), or the like, but example embodiments of the present disclosure are not limited thereto.

The first electrode layer AE may be electrically connected to the second source-drain electrode pattern layer SD2 through a contact hole in the second planarization layer PLN2.

A bank layer BNK may be configured to cover a portion of the first electrode layer AE.

A portion of the bank layer BNK corresponding to a light emitting area EA of a corresponding subpixel SP may be opened to form an opening area OPN.

For example, a portion of the first electrode layer AE may be exposed to the opening area OPN of the bank layer BNK.

An emission layer EL may be located on side surfaces of the bank layer BNK and in the opening area OPN of the bank layer BNK.

All or at least a portion of the emission layer EL may be located between adjacent portions of bank layers BNK.

In the opening area OPN of the bank layer BNK, the emission layer EL may contact the first electrode layer AE.

A second electrode layer CE may be disposed on the emission layer EL.

The second electrode layer CE may include a material with a relatively low work function, for example, a metal, an alloy, an electroconductive compound, or a mixture of two or more thereof.

For example, a transmissive electrode as the second electrode layer CE may be obtained by forming, in the form of a thin film, lithium (Li), magnesium (Mg), aluminum (Al), aluminum-lithium (Al—Li), calcium (Ca), magnesium-indium (Mg—In), magnesium-silver (Mg—Ag), and/or the like.

In this regard, various modifications may be made, such as forming transmissive electrodes using ITO or IZO in a structure where light emitting elements are configured to emit light toward the front of the display device 100 with a top emission structure.

The emission layer EL may include an organic material.

The emission layer EL may include a red mission layer R_EL disposed in a red subpixel Red SP, a green mission layer G_EL disposed in a green subpixel Green SP, and a blue mission layer B_EL disposed in a blue subpixel Blue SP.

For example, wavelengths of light emitted from the emission layers (R_EL, G_EL, and B_EL) may be, in a descending length order, the red emission layer R_EL, the green emission layer G_EL, and the blue emission layer B_EL.

The red mission layer R_EL may include a red host and a red dopant.

The red host may use Alq3, CBP, PVK, AND, TCTA, TPBI, TBADN, E3, DSA, or a mixture of two or more thereof, but example embodiments of the present disclosure are not limited thereto.

The red dopant may use PtOEP, Ir(piq)₃, Btp₂Ir(acac), Ir(2-phq)₂(acac), Ir(2-phq)₃, Ir(flq)₂(acac), Ir(fliq)₂(acac), or compounds containing DCM or DCJTB, but example embodiments of the present disclosure are not limited thereto.

The green mission layer G_EL may include a green host and a green dopant.

The green host may use Alq3, CBP, PVK, AND, TCTA, TPBI, TBADN, E3, DSA, or a mixture of two or more thereof, but example embodiments of the present disclosure are not limited thereto.

The green dopant may use Ir(ppy)₃ tris(2-phenylpyridine)iridium, Ir(ppy)₂ (acac)(Bis(2-phenylpyridine)(Acetylacetonato)iridium(III), Ir(mppy)₃ (tris(2-(4-tolyl)phenylpiridine)iridium, C545T 10-(2benzothiazolyl)-1,1,7,7-tetramethyl-2,3,6,7-tetrahydro-1H,5H,11H-[1]benzopyrano[6,7,8-ij]-quinolizin11-one, or the like, but example embodiments of the present disclosure are not limited thereto.

The blue mission layer B_EL may include a blue host and a blue dopant.

The blue host may use Alq3, CBP(4,4′-N,N′-dicabazole-biphenyl), PVK(poly(n-vinylcabazole), ADN(9,10-di(naphthalene-2-yl)anthracene), TCTA, TPBI(1,3,5-tris(N-phenylbenzimidazole-2-yl)benzene), TBADN(3-tert-butyl-9,10-di(naphth-2-yl)anthracene), E3, DSA(distyrylarylene), or a mixture of two or more thereof, but example embodiments of the present disclosure are not limited thereto.

The blue dopant may use compounds containing F₂Irpic, (F₂ppy)₂Ir(tmd), Ir(dfppz)₃, ter-fluorene, DPAVBi(4,4′-bis(4diphenylaminostyryl)biphenyl, TBPe, and/or the like, but example embodiments of the present disclosure are not limited thereto.

As described above, as some layers included in the stack structure of the light emitting element ED, the first electrode layer AE, the emission layer EL, and the second electrode layer CE have been discussed.

Hereinafter, as other layers included in the stack structure of the light emitting element ED, a hole injection layer HIL and a hole transport layer HTL are discussed with reference to FIG. 6A.

The hole injection layer HIL may be disposed on the first electrode layer AE and the bank layer BNK in the light emitting element ED.

The hole injection layer HIL may include at least one hole H on the bank layer BNK.

For example, the at least one hole H may be formed between an opening area OPN of a red subpixel Red SP and an opening area OPN of a blue subpixel Blue SP. In this implementation, since lateral leakage current LLC which is generated when the blue subpixel Blue SP is driven and flows along the hole injection layer HIL, can be blocked by the hole H, the red subpixel Red SP adjacent to the blue subpixel Blue SP can be prevented from being unintentionally driven and emitting an unintended color.

Accordingly, the hole H of the hole injection layer HIL can serve to minimize such lateral leakage current LLC.

FIG. 6A illustrates that the hole H is located in an inclined portion of the bank layer BNK, but example embodiments of the present disclosure are not limited to this. For example, the hole H may be located in a flat portion of the bank layer BNK.

FIG. 6A illustrates that only one hole H per light emitting element ED is formed, but example embodiments of the present disclosure are not limited to this. For example, a plurality of holes H may be formed per light emitting element ED.

In an example where a plurality of holes H are formed per light emitting element ED, the plurality of holes H may be configured to be spaced apart from each other on the bank layer BNK.

For example, in an example where holes H are configured to overlap with each other, a size of a hole resulting from the overlapping of the holes H may become greater. For example, one or more holes H may be formed in a flat portion or one or more of inclined portions, or two or more holes H may be formed across the one or more of the inclined portions and the flat portion, of the bank layer BNK.

An absolute value of a lowest unoccupied molecular orbital (LUMO) energy level of the hole injection layer HIL may be greater than an absolute value of an energy level of a metal included in the first electrode layer AE.

The hole injection layer HIL can prevent degradation of a hole transport layer HTL by confining electrons entering the hole injection layer HIL along the hole transport layer HTL.

In addition, hole injection from the first electrode layer AE having a low work function energy level can be facilitated due to the dipole property of the hole injection layer HIL.

For example, an amine derivative and/or the like may be used as a hole injection layer (HIL) material.

The hole injection layer HIL may include a p-type dopant to improve hole injection capability.

In one or more aspects, the hole transport layer HTL may be formed on the hole injection layer HIL using one or more suitable methods, such as vacuum deposition, spin coating, casting, langmuir-blodgett (LB) method, inkjet printing, laser printing, and/or the like.

When a voltage is applied between the first electrode layer AE and the second electrode layer CE of the light emitting element ED, holes passing through the hole transport layer HTL and electrons passing through an electron transport layer (not shown) may move to the emission layer EL and form excitons, this enabling the emission layer EL to emit visible light.

For example, a carbazole derivative such as N-phenylcarbazole, polyvinylcarbazole, and/or the like, and an amine derivative having an aromatic condensed ring such as NPB and/or the like may be used as a hole transport layer (HTL) material.

For example, TCTA, which may be used as a hole transport layer (HTL) material, can serve not only to transport holes but also to prevent excitons from diffusing from the emission layer EL.

A thickness of the hole transport layer may be about 5 nm to 100 nm, preferably 10 nm to 70 nm.

When the thickness of the hole transport layer satisfies this range, excellent hole transport characteristics can be obtained without a substantial increase in driving voltage.

In one or more aspects, the hole transport layer HTL may include a common hole transport layer (not shown) disposed on the hole injection layer HIL.

The hole transport layer HTL may include an emission auxiliary layer (not shown) disposed between the hole transport layer HTL and the common hole transport layer.

The emission auxiliary layer may include a red emission auxiliary layer, a green emission auxiliary layer, and a blue emission auxiliary layer disposed on the hole transport layer HTL.

For example, the emission auxiliary layer may serve to transport holes and may include a hole transport material (e.g., the hole transport layer (HTL) material). Each of the emission auxiliary layers may include the same material or compound or may include different materials or compounds.

The light emitting element ED may include an electron blocking layer (not shown) between the hole transport layer HTL and the emission layer EL.

In one or more aspects, although not shown in FIG. 6A, the light emitting element ED may include a hole blocking layer (not shown) located on the emission layer EL between the second electrode layer CE and the emission layer EL, an electron transport layer (not shown) located on the hole blocking layer, and an electron injection layer (not shown) located on the electron transport layer.

In one or more aspects, FIG. 6A illustrates that the light emitting element ED has a single stack structure as an example, but example embodiments of the present disclosure are not limited to this. For example, the light emitting element ED may have a multi-stack structure including a plurality of emission layers EL.

Referring to FIG. 6A, an encapsulation layer ENCAP may be disposed on the light emitting element ED.

The encapsulation layer ENCAP may have a single-layer structure or a multi-layer structure.

For example, the encapsulation layer ENCAP may include a first encapsulation layer, a second encapsulation layer, and a third encapsulation layer.

In this example, the first encapsulation layer and the third encapsulation layer may be inorganic layers, and the second encapsulation layer may be an organic layer.

Among the first encapsulation layer, the second encapsulation layer, and the third encapsulation layer, the second encapsulation layer may be the thickest and may serve as a planarization layer.

The encapsulation layer ENCAP may be disposed on the second electrode layer CE and disposed closest to the light emitting element ED.

The first encapsulation layer may include an inorganic insulating material capable of being deposited using low-temperature deposition.

The first encapsulation layer may include a metal oxide layer, a metal nitride layer, a metal nitride layer, or the like.

For example, the first encapsulation layer may include MoOₓ(x=2˜4), Al₂O₃, Sb₂O₃, BaO, CdO, CaO, Ce₂O₃, CoO, Cu₂O, DyO, GdO, HfO₂, La₂O₃, Li₂O, MgO, NbO, NiO, Nd₂O₃, PdO, Sm₂O₃, ScO, SiO₂, SrO, Ta₂O₃, TiO, WO₃, VO₂, YbO, Y₂O₃, ZnO, ZrO, AlN, BN, NbN, SiN, TaN, TiN, VN, YbN, ZrN, SiON, AlON, or mixtures thereof, but example embodiments of the present disclosure are not limited thereto.

Since the first encapsulation layer can be deposited in a low temperature atmosphere, during the deposition process, the first encapsulation layer can prevent the emission layer EL including an organic material vulnerable to a high temperature atmosphere from being damaged.

The second encapsulation layer may be configured to have a smaller area than the first encapsulation layer.

In this implementation, the second encapsulation layer may be configured to expose both ends of the first encapsulation layer.

The second encapsulation layer can serve as a buffer for relieving stress between corresponding layers while the display device 100 is curved or bent, and also serve to enhance planarization performance.

For example, the second encapsulation layer may include an organic insulating material, such as acrylic resin, epoxy resin, polyimide, polyethylene, silicon oxycarbon (SiOC), or the like.

The second encapsulation layer may be disposed, for example, using an inkjet technique.

The third encapsulation layer may be disposed over the substrate SUB over which the second encapsulation layer is disposed such that the third encapsulation layer covers a respective top surface and respective one or more side surfaces of at least one of the second encapsulation layer and the first encapsulation layer.

The third encapsulation layer can minimize or shield external moisture or oxygen from penetrating into the first encapsulation layer and the second encapsulation layer.

For example, the third encapsulation layer may include an inorganic insulating material, such as silicon nitride (SiNx), silicon oxide (SiOx), silicon oxynitride (SiON), aluminum oxide (Al2O3), or the like.

Hereinafter, a stack structure of the first optical area OA1 is described with reference to FIG. 6B.

FIG. 6B is an example cross-sectional view taken along line B-B′ of FIG. 5B.

The configurations of a driving transistor DRT and a light emitting element ED of FIG. 6B may be substantially the same as those of the driving transistor DRT and light emitting element ED of FIG. 6A.

Similar to FIG. 6A, in the example of FIG. 6B, at least one hole H may be formed between an opening area OPN of a red subpixel Red SP and an opening area OPN of a blue subpixel Blue SP. In this implementation, since lateral leakage current LLC which is generated when the blue subpixel Blue SP is driven and flows along a hole injection layer HIL, can be blocked by the hole H, the red subpixel Red SP adjacent to the blue subpixel Blue SP can be prevented from being unintentionally driven and emitting an unintended color.

For example, one or more holes of the hole injection layer HIL may be formed not only in the normal area NA of FIG. 6A but also in the first optical area OA1 of FIG. 6B.

In this example, lateral leakage current LLC can be prevented by forming such a hole H in the hole injection layer HIL on a bank layer between a subpixel of one color and an adjacent subpixel of another color, and thereby, the subpixel of the another color can be prevented from being unintentionally driven to emit light, this enabling the display device 100 to be driven with low power.

Therefore, to reduce a difference in luminance between the normal area NA and the optical areas (OA1, OA2) by increasing the lifetime of light emitting elements ED in the optical areas (OA1, OA2) through low-power driving, it may be desirable that one or more holes H are formed only in the one or more optical areas (OA1 and/or OA2).

Referring to FIG. 6B, it should be noted that respective stack structures of a non-transmissive area (e.g., the remaining area except for a transmissive area TA1) in the first optical area OA1 and the normal area NA discussed above may be substantially the same.

Accordingly, hereinafter, a stack structure of a first transmissive area TA1 in the first optical area OA1 is described in detail.

A second electrode layer CE may be disposed in the normal area NA and the non-transmissive area of the first optical area OA1, but the second electrode layer CE may not be disposed in the first transmissive area TA1 of the first optical area OA1.

For example, the first transmissive area TA1 of the first optical area OA1 may correspond to an opening (or an opening area) of the second electrode layer CE.

In one or more aspects, a light shield layer LSL including at least one of a first metal layer ML1 and a second metal layer ML2 may be disposed in the normal area NA and the non-transmissive area of the first optical area OA1, but a light shield layer LSL may not be disposed in the first transmissive area TA1 of the first optical area OA1.

For example, the first transmissive area TA1 of the first optical area OA1 may correspond to an opening (or an opening area) of the light shield layer LSL.

In one or more aspects, the substrate SUB and various types of insulating layers (BUF, GI, ILD1, ILD2, PAS, PLN1, PLN2, BNK, and ENCAP) disposed in the normal area NA and the non-transmissive area of the first optical area OA1 may be equally disposed in the first transmissive area TA1 of the first optical area OA1.

For example, among elements or layers disposed in the normal area NA and the non-transmissive area of the first optical area OA1, material layers with electrical properties (e.g., a metal material layer, a semiconductor layer, and the like) except for the insulating layers may not be disposed in the first transmissive area TA1 of the first optical area OA1.

For example, referring to FIG. 6B, metal material layers (ML1, ML2, GATE, GM, TM, SD1, and SD2) and semiconductor layers ACT associated with transistors may not be disposed in the first transmissive area TA1 of the first optical area OA1.

In one or more aspects, a first electrode layer AE and the second electrode layer CE included in a light emitting element ED may not be disposed in the first transmission area TA1.

In one or more aspects, it should be noted that an emission layer EL included in the light emitting element ED may be disposed or may not be disposed in the first transmission area TA1 according to a design requirement.

Thus, since the material layers with electrical properties (e.g., a metal material layer, a semiconductor layer, and the like) are not disposed in the first transmissive area TA1 of the first optical area OA1, the transmittance of the first transmissive area TA1 of the first optical area OA1 can be improved.

Therefore, the first optical electronic device 11 can receive light passing through the first transmissive area TA1 and perform predefined functions (e.g., image sensing, image capturing, and the like).

Since all or at least a portion of the first transmissive area TA1 in the first optical area OA1 overlaps with the first optical electronic device 11, it is necessary to increase the transmittance of the first transmissive area TA1 in the first optical area OA1 to enable the first optical electronic device 11 to normally operate.

In one or more aspects, to implement this configuration, as shown in FIG. 6B, among the plurality of insulating layers, a first planarization layer PLN1 may include at least one uneven portion (e.g., at least one recessed portion or/and at least one protrude portion).

For example, the first planarization layer PLN1 may be an organic insulating layer.

In the example where a portion of the first planarization layer PLN1 is recessed and/or protrudes downwardly, a second planarization layer PLN2 may substantially serve as a planarization layer.

In one or more aspects, the second planarization layer PLN2 may also be depressed and/or protrude downwardly. In this implementation, a second encapsulation layer PCL may substantially serve as a planarization layer.

Referring to FIG. 6B, a portion of the first planarization layer PLN1, which protrudes downwardly, and a portion of a passivation layer PAS, which is disposed along the bottom of the portion of the first planarization layer PLN1, may pass through insulating layers (ILD1, ILD2, and GI) for forming a transistor DRT and a buffer layer SUB located under the insulating layers, and then, the portion of the passivation layer PAS may reach a portion (e.g., an upper portion, a side portion, or the like) of the substrate SUB.

In one or more aspects, the substrate SUB may include at least one recessed portion to improve transmittance.

For example, in the first transmissive area TA1, an upper portion of the substrate SUB may be recessed, or a portion of the substrate SUB may be perforated.

Hereinafter, a stack structure of the second optical area OA2 is described with reference to FIGS. 6C to 6D.

FIGS. 6C and 6D are example cross-sectional views taken along line C-C′ of FIG. 5C.

The configurations of each driving transistor DRT and each light emitting element ED of FIGS. 6C and 6D may be substantially the same as those of the driving transistor DRT and light emitting element ED of FIG. 6A.

In each of the examples of FIGS. 6C and 6D, at least one hole H may be formed between an opening area OPN of a red subpixel Red SP and an opening area OPN of a green subpixel Green SP. In this implementation, since lateral leakage current LLC which is generated when the green subpixel Green SP is driven and flows along a hole injection layer HIL, can be blocked by the hole H, the red subpixel Red SP adjacent to the green subpixel Green SP can be prevented from being unintentionally driven and emitting an unintended color.

For example, one or more holes of the hole injection layer HIL may be formed not only in the normal area NA of FIG. 6A but also in the second optical area OA2 of FIGS. 6C and 6D.

In this example, lateral leakage current LLC can be prevented by forming such a hole H in the hole injection layer HIL on a bank layer between a subpixel of one color and an adjacent subpixel of another color, and thereby, the subpixel of the another color can be prevented from being unintentionally driven to emit light, this enabling the display device 100 to be driven with low power.

Referring to FIGS. 6C and 6D, it should be noted that respective stack structures of a non-transmissive area (e.g., the remaining area except for a transmissive area TA2) in the second optical area OA2 and the normal area NA discussed above may be substantially the same.

Accordingly, hereinafter, a stack structure of a second transmissive area TA2 in the second optical area OA2 is described in detail.

A second electrode layer CE may be disposed in the normal area NA and the non-transmissive area of the second optical area OA2, but the second electrode layer CE may not be disposed in the second transmissive area TA2 of the second optical area OA2.

For example, the second transmissive area TA2 of the second optical area OA2 may correspond to an opening (or an opening area) of the second electrode layer CE.

In one or more aspects, a light shield layer LSL including at least one of a first metal layer ML1 and a second metal layer ML2 may be disposed in the normal area NA and the non-transmissive area of the second optical area OA2, but a light shield layer LSL may not be disposed in the second transmissive area TA2 of the second optical area OA2.

When the transmittance of the second optical area OA2 and the transmittance of the first optical area OA1 are substantially the same, a stack structure of the second transmissive area TA2 of the second optical area OA2 may be substantially the same as the stack structure of the first transmissive area TA1 of the first optical area OA1.

When the transmittance of the second optical area OA2 and the transmittance of the first optical area OA1 are different, a stack structure of the second transmissive area TA2 of the second optical area OA2 may be at least partially different from that of the first transmissive area TA1 of the first optical area OA1.

For example, when the transmittance of the second optical area OA2 is lower than the transmittance of the first optical area OA1, the second transmissive area TA2 of the second optical area OA2 may not have a transmittance improvement structure.

For example, a first planarization layer PLN1 and a passivation layer PAS may not be recessed and/or protrude.

For example, a width of the second transmissive area TA2 of the second optical area OA2 may be smaller than a width of the first transmissive area TA1 of the first optical area OA1.

In one or more aspects, the substrate SUB and various types of insulating layers (BUF, GI, ILD1, ILD2, PAS, PLN1, PLN2, BNK, and ENCAP) disposed in the normal area NA and the non-transmissive area of the second optical area OA2 may be equally disposed in the second transmissive area TA2 of the second optical area OA2.

For example, among elements or layers disposed in the normal area NA and the non-transmissive area of the second optical area OA2, material layers with electrical properties (e.g., a metal material layer, a semiconductor layer, and the like) except for the insulating layers may not be disposed in the second transmissive area TA2 of the second optical area OA2.

For example, referring to FIGS. 6C and 6D, metal material layers (ML1, ML2, GATE, GM, TM, SD1, and SD2) and semiconductor layers (ACT) associated with transistors may not be disposed in the second transmissive area TA2 of the second optical area OA1.

In one or more aspects, a first electrode layer AE and the second electrode layer CE included in a light emitting element ED may not be disposed in the second transmission area TA2.

In one or more aspects, it should be noted that an emission layer EL included in the light emitting element ED may be disposed or may not be disposed in the second transmission area TA2 according to a design requirement.

Thus, since the material layers with electrical properties (e.g., a metal material layer, a semiconductor layer, and the like) are not disposed in the second transmissive area TA2 of the second optical area OA2, the transmittance of the second transmissive area TA2 of the second optical area OA2 can be improved.

Therefore, the second optical electronic device 12 can receive light passing through the second transmissive area TA2 and perform predefined functions (e.g., detecting approaching objects or human bodies, detecting ambient light, or the like.

As described above, the stack structures of the examples of FIGS. 6C to 6D have been discussed.

Hereinafter, the presence or absence of a protective layer PL in FIGS. 6C and 6D is described.

Referring to FIGS. 6C and 6D, a protective layer PL may be disposed in the second transmissive area TA2.

FIGS. 6C and 6D illustrate examples where the protective layer PL is disposed in the second transmissive area TA2 as an example, but example embodiments of the present disclosure are not limited to this. For example, this configuration may be equally applied to the first transmissive area TA1 of FIG. 6B.

The protective layer PL may include an organic material and be configured to cover at least a portion of the transmissive areas (TA1 and TA2) using a fine metal mask (FMM).

The protective layer PL may be used to improve the light transmittance of the first transmissive area TA1 or the second transmissive area TA2 and to effectively pattern the second electrode layer CE formed in a corresponding light emitting area EA.

For example, after forming the protective layer PL in the second transmissive area TA2 using the fine metal mask FMM, the second electrode layer CE may be deposited in a corresponding light emitting area EA using an open metal mask OMM, and thus, the second electrode layer CE can be effectively formed in the light emitting area EA except for the protective layer PL.

Accordingly, referring to FIG. 6D, the protective layer PL and the second electrode layer CE may be located in the same layer.

However, as shown in FIG. 6D, example embodiments of the present disclosure are not limited to the example where the protective layer PL is maintained in the second transmissive area TA2. For example, to increase the transmittance of the second transmissive areas TA2, the protective layer PL may be removed after the second electrode layer CE is formed.

For example, as shown in FIG. 6C, the protective layer TL may not remain in the second transmissive area TA2.

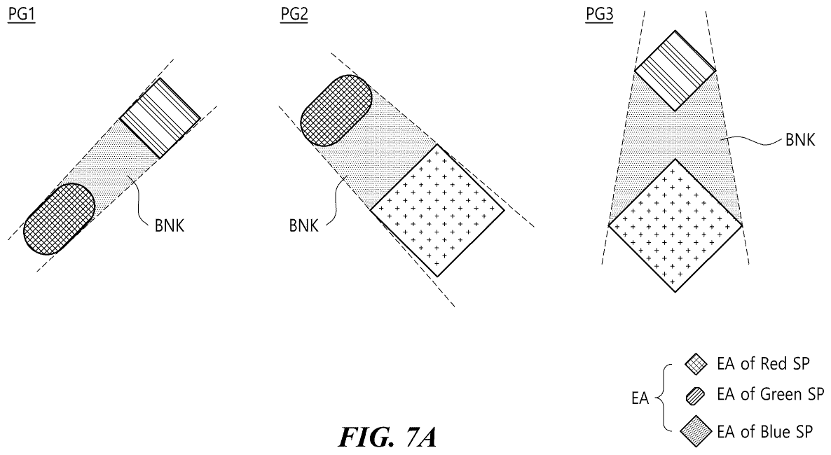

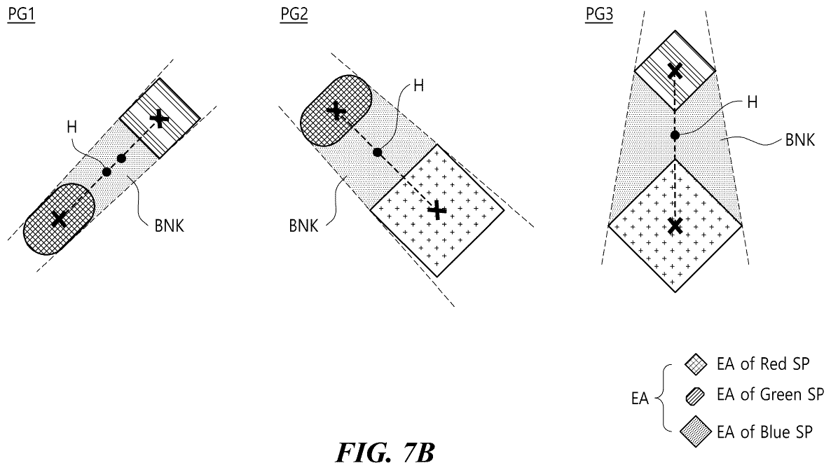

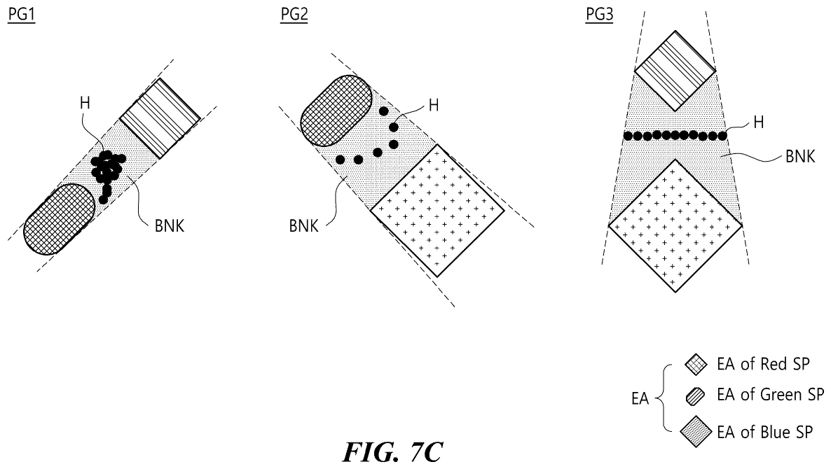

FIGS. 7A, 7B, and 7C are example enlarged plan views of the first pixel group PG1, the second pixel group PG2, and the third pixel group PG3 of FIG. 5A.

Referring to FIG. 7A along with FIG. 6A, light emitting areas EA of subpixels (Red SP, Green SP, and Blue SP) may be substantially the same as opening areas of the bank layer BNK, respectively.

In this implementation, at least one hole H of the hole injection layer may be located in at least one of a portion of the bank layer BNK between a red subpixel Red SP and a green subpixel Green SP adjacent to the red subpixel Red SP in the first pixel group PG1, a portion of the bank layer BNK between a green subpixel Green SP and a blue subpixel Blue SP adjacent to the green subpixel Green SP in the second pixel group PG2, and a portion of the bank layer BNK between a blue subpixel Blue SP and a red subpixel Red SP adjacent to the blue subpixel Blue SP in the third pixel group PG3.

That is, portions indicated as bank layers BNK in FIG. 7A may refer to areas where holes H of the hole injection layer are located.

However, holes H of the hole injection layer according to example embodiments of the present disclosure are not necessarily located only in the portions indicated as the bank layer BNK in FIG. 7A, and may be located in areas other than opening areas of the bank layer BNK.

Preferably, holes H may be located on a respective portion of the bank layer BNK between each blue subpixel Blue SP and each red subpixel Red SP adjacent to each blue subpixel Blue SP.

Referring to FIG. 7A, each portion indicated as the bank layer BNK may mean an area defined by two virtual straight lines running while touching two adjacent subpixels and respective inner edges facing to each other among respective edges of opening areas of the subpixels.

Referring to FIG. 7B along with FIG. 6A, at least one hole H of the hole injection layer may be located on at least one of a line connecting a center point of a red subpixel Red SP and a center point of an adjacent blue subpixel Blue SP, a line connecting a center point of a red subpixel Red SP and a center point of an adjacent green subpixel Green SP, and a line connecting a center point of a blue subpixel Blue SP and a center point of an adjacent green subpixel Green SP.

Preferably, holes H of the hole injection layer may be located on lines connecting the center point of each red subpixel Red SP and the center point of each blue subpixel Blue SP adjacent to each red subpixel Red SP.

Even in this example, holes H may be located in an area other than opening areas of the bank layer.

As described above, a plurality of holes H may be formed, and may be arranged to be spaced apart from each other.

Referring to FIG. 7C, holes H may overlap with each other to form one large hole H, be located apart from each other, or be located in a line shape.

The locations of the holes H described above with reference to FIGS. 7A to 7C are merely examples, and shapes, numbers, and locations of holes H according to example embodiments of the present disclosure are not necessarily limited thereto.

Although the description related to the holes H have been provided based on three pixel groups, that is, the first pixel group PG1, the second pixel group PG2, and the third pixel group PG3, the specific shapes, numbers, and locations of the holes H are not limited to only a specific pixel group among pixel groups. For example, various embodiments may be available in such a manner that discussions on the holes H in the first pixel group PG1 are also applied the holes H in the second pixel group PG2.

Hereinafter, a method of manufacturing the display device 100 is described.

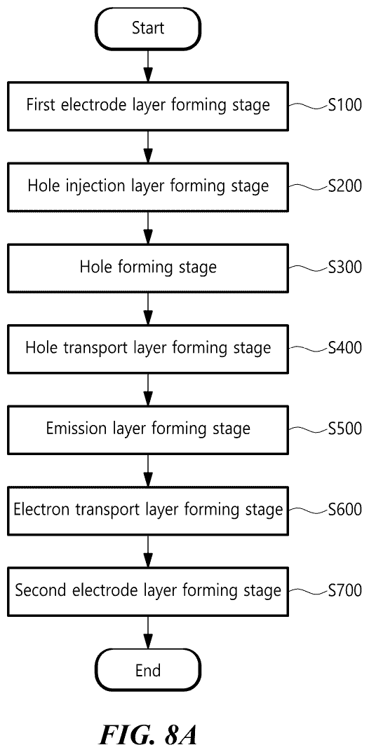

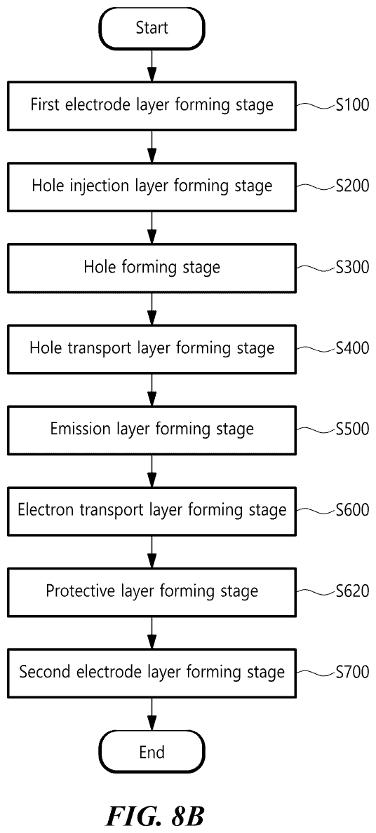

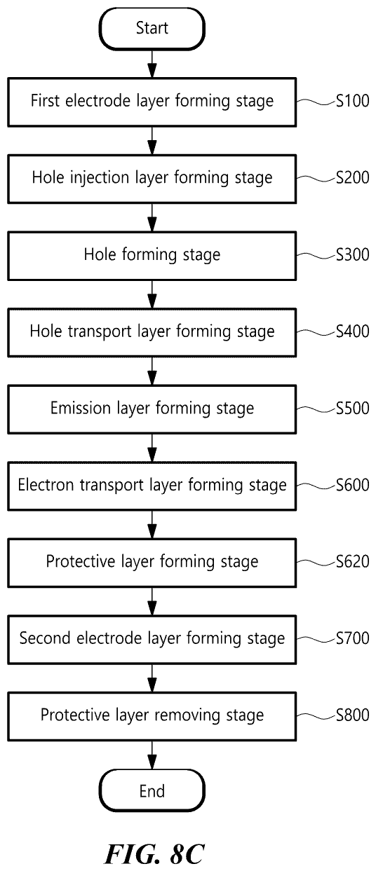

FIGS. 8A, 8B, and 8C are flow diagrams illustrating an example method of manufacturing the display device 100 according to aspects of the present disclosure.

Referring to FIG. 8A, in one or more example embodiments, a method of manufacturing the display device 100 may include a first electrode layer forming stage S100, a hole injection layer forming stage S200, a hole forming stage S300, a hole transport layer forming stage S400, an emission layer forming stage S500, an electron transport layer forming stage S600, and a second electrode layer forming stage S700.

In discussing the method of manufacturing the display device 100 according to aspects of the present disclosure, it should be noted that respective configurations of a first electrode layer, a hole injection layer, one or more holes, a hole transport layer, an emission layer, an electron transport layer, and a second electrode layer are equal to the respective configurations of the first electrode layer AE, the hole injection layer HIL, the one or more holes H, the hole transport layer HTL, the emission layer EL, the electron transport layer, and the second electrode layer CE of the display device 100 according to the example embodiments described above unless explicitly stated otherwise.

The first electrode layer, the hole injection layer, the hole transport layer, the emission layer, the electron transport layer, and the second electrode layer are formed in the first electrode layer forming stage S100, the hole injection layer forming stage S200, the hole transport layer forming stage S400, the emission layer forming stage S500, the electron transport layer forming stage S600, and the second electrode layer forming stage S700, respectively, using an open metal mask (OMM) or a fine metal mask (FMM).

In the hole forming stage S300, one or more holes H may be formed in the hole injection layer HIL using a laser or a laser beam.

The forming of one or more holes H may mean that one or more portions of the hole injection layer HIL where the one or more holes H are formed are removed.

The one or more holes H formed in the hole forming stage S300 may be filled with a hole transport layer material for the hole transport layer HTL in the hole transport layer forming stage S400 such that the holes H has the hole transport layer material therein. The term “filled with” does not necessarily exclude the presence of other materials unless the embodiments specifically state “completely filled with” or “exclusively filled with.”

Accordingly, as the one or more holes H are filled with the hole transport layer material, the hole transport layer HTL may contact the bank layer in the one or more holes H.

Referring to FIG. 8B, a protective layer forming stage S620 of forming a protective layer on the electron transport layer may be further included before the second electrode layer forming stage S700 of FIG. 8A.

For example, the protective layer forming stage S620 may be performed between the electron transport layer forming stage S600 and the second electrode layer forming stage S700, but example embodiments of the present disclosure are not limited to this.

It should be noted that the protective layer in the protective layer forming stage S620 may be substantially the same as the protective layer PL described in FIG. 6D.

The protective layer PL may include an organic material and be deposited to cover at least a portion of one or more transmissive areas (TA1 and/or TA2) using a fine metal mask (FMM).

The protective layer PL may be used to improve the light transmittance of the one or more transmissive areas (TA1 and/or TA2), and effectively pattern the second electrode layer CE formed in a corresponding light emitting area in the second electrode layer forming stage S700.

For example, after forming the protective layer in the one or more transmissive areas (TA1 and/or TA2) using the fine metal mask (FMM), by depositing the second electrode layer CE in the light emitting area EA using the open metal mask (OMM), the second electrode layer CE may be effectively formed in the light emitting area except for the protective layer.

Referring to FIG. 8C, a protective layer removing stage S800 of removing the protective layer formed in the protective layer forming stage S620 may be further included after the second electrode layer forming stage S700 of FIG. 8B.

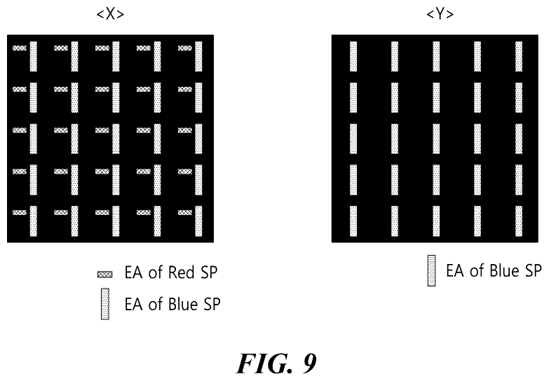

FIG. 9 is an example schematic diagram illustrating the presence of lateral leakage current in the display device 100 according to aspects of the present disclosure.

Referring to FIG. 9, an <X> image shows that a hole H of a hole injection layer is not formed on a bank layer between a blue subpixel Blue SP and a red subpixel Red SP adjacent to the blue subpixel Blue SP, and a <Y> image shows that a hole H of the hole injection layer is formed on a portion of the bank layer between a blue subpixel Blue SP and a red subpixel Red SP adjacent to the blue subpixel Blue SP.

Referring to FIG. 9, in the <X> image, when a hole H is not formed in the hole injection layer, when the corresponding blue light emitting element ED is driven by a driving transistor, lateral leakage current LLC flowing through the hole injection layer may move from the blue light emitting element to the corresponding red light emitting element, and thereby, the red light emitting element may be driven to emit red light.

In contrast, when the hole H is formed in the hole injection layer, as shown in the <Y> image, the lateral leakage current LLC flowing through the hole injection layer cannot move from the blue light emitting element to the red light emitting element, and as a result, the red light emitting element cannot be driven, resulting in the red light emitting element not emitting light.

Therefore, as shown in the <Y> image, by forming a hole in the hole injection layer, lateral leakage current LLC can be blocked and emission of an unintended color can be prevented.

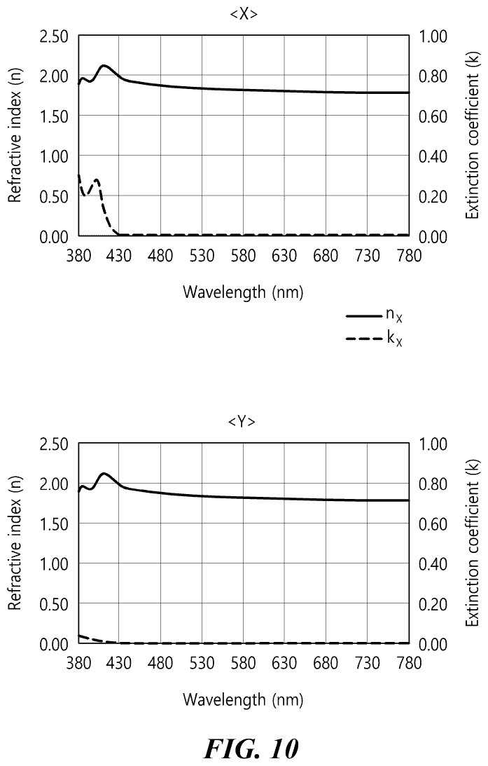

FIG. 10 is an example graph illustrating changes in an extinction coefficient and a refractive index with respect to wavelengths in the display device 100 according to aspects of the present disclosure.

It should be noted that the respective configurations of the <X> image and the <Y> image of FIG. 9 with respect to the presence or absence of a hole in a hole injection layer equally correspond to an <X> grape and a <Y> grape of FIG. 10, respectively.

In the <X> configuration, as a hole is not formed in the hole injection layer, since light with short wavelengths, which is required to be detected by one or more optical electronic devices (11 and/or 12), is absorbed by the hole injection layer, thereby, there arises a problem in that the detection performance of the one or more optical electronic devices (11 and/or 12) can be reduced.

In contrast, as in the <Y> configuration, when a hole is formed in the hole injection layer, since an amount of the hole injection layer in the hole area is reduced, a rate of absorbing light with short wavelengths can be reduced.

In other words, in the <Y> graph, it can be seen that the extinction coefficient k corresponding to short wavelengths (380 nm to 430 nm) is reduced from 0.2 to 0.4 k_{X} to less than 0.2 k_{Y}.

Accordingly, as the extinction coefficient k_{Y} is reduced in short wavelengths, the sensing performance of one or more optical electronic devices (11 and/or 12) configured to sense short wavelengths can be improved.

Referring to FIG. 10, it can be seen that even when a hole is formed in the hole injection layer, there is little change in the refractive index n in short wavelengths (380 nm to 430 nm), and therefore, the refractive index cannot be affected.

The example embodiments described above will be briefly described as follows.

According to the example embodiments of the present disclosure, a display device can be provided that includes: a substrate on which a normal area allowing a plurality of first pixels to be disposed and having a first resolution and an optical area allowing a plurality of second pixels to be disposed and having a second resolution lower than the first resolution are defined; a first electrode layer located over the substrate; a bank layer located over the substrate, covering a portion of the first electrode layer, and including an opening area; a hole injection layer located on the first electrode layer and the bank layer, and including at least one hole located on the bank layer; a hole transport layer located on the hole injection layer; and an emission layer located on the hole transport layer.

In one or more aspects, the at least one hole has the hole transport layer therein.

In one or more aspects, the hole transport layer may contact the bank layer at the at least one hole.

In one or more aspects, the at least one hole may be located in an area other than the opening area.

In one or more aspects, the plurality of first pixels or the plurality of second pixels may include a plurality of red subpixels, a plurality of green subpixels, and a plurality of blue subpixels. The at least one hole may be located in at least one of a portion of the bank layer between a red subpixel among the plurality of red subpixels and a green subpixel adjacent to the red subpixel among the plurality of green subpixels, a portion of the bank layer between the green subpixel among the plurality of green subpixels and a blue subpixel adjacent to the green subpixel among the plurality of blue subpixels, and a portion of the bank layer between the blue subpixel among the plurality of blue subpixels and the red subpixel adjacent to the blue subpixel among the plurality of red subpixels.

In one or more aspects, the at least one hole may be located in a portion of the bank layer between the blue subpixel and the red subpixel.

In one or more aspects, the at least one hole may be located on at least one of a line connecting a center point of a red subpixel among the plurality of red subpixels and a center point of a blue subpixel adjacent to the red subpixel among the plurality of blue subpixels, a line connecting a center point of the red subpixel among the plurality of red subpixels and a center point of a green subpixel adjacent to the red subpixel among the plurality of green subpixels, and a line connecting a center point of the blue subpixel among the plurality of blue subpixels and a center point of the green subpixel adjacent to the blue subpixel among the plurality of green subpixels.

In one or more aspects, the at least one hole may be located on a line connecting a center point of the blue subpixel and a center point of the red subpixel.

In one or more aspects, the at least one hole may be located in the normal area or the optical area.

In one or more aspects, the optical area may include a transmissive area and a non-transmissive area, and the second electrode layer may be located on the emission layer in the non-transmissive area.

In one or more aspects, the display device may further include a protective layer disposed on the emission layer in the transmissive area.

In one or more aspects, the protective layer and the second electrode layer may be disposed in the same layer.

In one or more aspects, the transmissive area may have a circular, oval or polygonal shape.

In one or more aspects, the hole injection layer may include a p-type dopant.

In one or more aspects, the at least one hole may be configured not to allow current to flow in the at least one hole.

In one or more aspects, the at least one hole is located in an inclined portion or a flat portion of the bank layer.

In one or more aspects, the display device comprises a plurality of holes, the plurality of holes are separated from each other, overlapped with each other, or provided in a line shape.

According to the example embodiments of the present disclosure, a method of manufacturing the display device can be provided that includes forming a first electrode layer, forming a hole injection layer on the first electrode layer, forming a hole in the hole injection layer, forming a hole transport layer on the hole injection layer and filling the hole with the hole transport layer, forming an electron transport layer on an emission layer, and forming a second electrode layer on the electron transport layer.

In one or more aspects, the method of manufacturing the display device may further include forming a protective layer on the electron transport layer before forming the second electrode layer.

In one or more aspects, the method of manufacturing the display device may further include removing the protective layer after the second electrode layer is formed.

According to the example embodiments of the present disclosure, a display device can be provided that includes a substrate on which a normal area disposed with a plurality of first pixels and having a first resolution and an optical area disposed with a plurality of second pixels and having a second resolution lower than the first resolution are defined, wherein at least one of the normal area and the optical area comprises a plurality of subpixels, each of the plurality of subpixels comprises a light emitting element above the substrate, wherein the light emitting element comprises: a first electrode layer; a hole injection layer located on the first electrode layer and comprising at least one hole; a hole transport layer located on the hole injection layer; an emission layer located on the hole transport layer; and a second electrode layer located on the emission layer.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device, comprising:
a substrate on which a normal area allowing a plurality of first pixels to be disposed and having a first resolution and an optical area allowing a plurality of second pixels to be disposed and having a second resolution lower than the first resolution are defined;
a first electrode layer on the substrate;
a bank layer on the substrate, covering a portion of the first electrode layer, and comprising an opening area;
a hole injection layer on the first electrode layer and the bank layer, and comprising at least one hole on the bank layer;
a hole transport layer on the hole injection layer; and
an emission layer on the hole transport layer.

2. The display device of claim 1, wherein the at least one hole has the hole transport layer therein.

3. The display device of claim 1, wherein the hole transport layer contacts the bank layer at the at least one hole.

4. The display device of claim 1, wherein the at least one hole is located in an area other than the opening area.

5. The display device of claim 1, wherein the plurality of first pixels or the plurality of second pixels comprise a plurality of red subpixels, a plurality of green subpixels, and a plurality of blue subpixels, and
wherein the at least one hole is located in at least one of a portion of the bank layer between a red subpixel among the plurality of red subpixels and a green subpixel adjacent to the red subpixel among the plurality of green subpixels, a portion of the bank layer between the green subpixel among the plurality of green subpixels and a blue subpixel adjacent to the green subpixel among the plurality of blue subpixels, and a portion of the bank layer between the blue subpixel among the plurality of blue subpixels and the red subpixel adjacent to the blue subpixel among the plurality of red subpixels.

6. The display device of claim 5, wherein the at least one hole is located in the portion of the bank layer between the blue subpixel and the red subpixel.

7. The display device of claim 5, wherein the at least one hole is located on at least one of a line connecting a center point of the red subpixel and a center point of the green subpixel, a line connecting a center point of the green subpixel and a center point of the blue subpixel, and a line connecting a center point of the blue subpixel and a center point of the red subpixel.

8. The display device of claim 7, wherein the at least one hole is located on the line connecting the center point of the blue subpixel and the center point of the red subpixel.

9. The display device of claim 1, wherein the at least one hole is located in the normal area or the optical area.

10. The display device of claim 1, wherein the optical area comprises a transmissive area and a non-transmissive area, and the second electrode layer is located on the emission layer in the non-transmissive area.

11. The display device of claim 10, further comprising a protective layer disposed on the emission layer in the transmissive area.

12. The display device of claim 11, wherein the protective layer and the second electrode layer are disposed in a same layer.

13. The display device of claim 1, wherein the hole injection layer comprises a p-type dopant.

14. The display device of claim 4, wherein the at least one hole is located in an inclined portion or a flat portion of the bank layer.

15. The display device of claim 1, wherein the display device comprises a plurality of holes, the plurality of holes are separated from each other, overlapped with each other, or provided in a line shape.

16. A method of manufacturing a display device, the method comprising:
forming a first electrode layer;
forming a hole injection layer on the first electrode layer;
forming a hole in the hole injection layer;
forming a hole transport layer on the hole injection layer and filling the hole with the hole transport layer;
forming an emission layer on the hole transport layer;
forming an electron transport layer on the emission layer; and
forming a second electrode layer on the electron transport layer.

17. The method of claim 16, further comprising: forming a protective layer on the electron transport layer before forming the second electrode layer.

18. The method of claim 17, further comprising: removing the protective layer after the second electrode layer is formed.

19. A display device, comprising:
a substrate on which a normal area disposed with a plurality of first pixels and having a first resolution and an optical area disposed with a plurality of second pixels and having a second resolution lower than the first resolution are defined,
wherein at least one of the normal area and the optical area comprises a plurality of subpixels, each of the plurality of subpixels comprises a light emitting element above the substrate,
wherein the light emitting element comprises:
a first electrode layer;
a hole injection layer on the first electrode layer and comprising at least one hole;
a hole transport layer on the hole injection layer;
an emission layer on the hole transport layer; and
a second electrode layer on the emission layer.

20. The display device of claim 19, wherein the display device also comprises a bank layer between the first electrode layer and the hole injection layer, and a portion of the bank layer corresponding to a light emitting area of each subpixel forms an opening area, and
wherein the at least one hole is located between opening areas of adjacent subpixels.
